(19) United States
(12) Patent Application Publication
(10) Pub. No.: US 2024/0153874 A1
(43) Pub. Date: May 9, 2024

(54) Metal Gate Interconnect for Forksheet and Related Semiconductor Structures

(71) Applicant: Taiwan Semiconductor Manufacturing Company, Ltd., Hsin-Chu (TW)

(72) Inventors: Yi-Ju Chen, Tainan City (TW); Chung-Ting Li, Hsinchu (TW)

(21) Appl. No.: 18/159,773

(22) Filed: Jan. 26, 2023

Related U.S. Application Data
(60) Provisional application No. 63/382,205, filed on Nov. 3, 2022.

(51) Int. Cl. H01L 23/528; H01L 21/8234; H01L 23/48; H01L 23/522; H01L 29/06; H01L 29/417; H01L 29/66; H01L 29/775; H01L 29/786; H10B 10/00

(52) U.S. Cl. CPC H01L 23/5283; H01L 21/823412; H01L 21/823418; H01L 21/823475; H01L 23/481; H01L 23/5226; H01L 29/0673; H01L 29/41733; H01L 29/66439; H01L 29/775; H01L 29/78696; H10B 10/125

(57) ABSTRACT

A semiconductor device includes a forksheet structure extending lengthwise along a first direction over a substrate. The forksheet structure has a dielectric wall separating a stack of n-type nanostructures from a stack of p-type nanostructures. A gate structure is over the forksheet structure, the gate structure extending lengthwise along a second direction perpendicular to the first direction. The gate structure is in direct contact with the stack of n-type and p-type nanostructures and in direct contact with the dielectric wall. A first gate interconnect is over and in direct contact with the gate structure and a first gate via is over and in direct contact with the first gate interconnect.

### PRIORITY DATA

This application claims priority to U.S. Provisional Patent Application Ser. No. 63/382,205 filed on Nov. 3, 2022, the entire disclosure of which is herein incorporated by reference in its entirety.

### BACKGROUND

Multi-gate semiconductor devices such as fin field-effect-transistors (FETs) and gate-all-around (GAA) FETs have been introduced to improve gate control by increasing gate-channel coupling and reducing off-state current. With the ever-increasing demand to scale down integrated circuit (IC) dimensions while increasing device performance, continued advances in the multi-gate semiconductor devices require greater advances in semiconductor manufacturing processes and technology.

One type of GAA FET is the forksheet FET, which includes a metal gate over a stack of nanosheet channels separated into two portions by a forksheet dielectric wall. The dielectric wall allows n-type devices and p-type devices to be formed close to each other. Due to the presence of the dielectric wall, the metal gate needs to have a minimum thickness to prevent a gate via structure from landing on the dielectric wall and causing an open circuit. However, a greater metal gate thickness introduces undesirable parasitic capacitance between the metal gate and nearby source/drain contacts. Further, the gate via structures that land on the metal gate may suffer from high resistance due to having high aspect ratio or limitations to the metal fill material. Still further, in some conventional processes related to static random access memory (SRAM) devices, shared butted contacts between metal gate and source/drain contacts place limitations and constraints to SRAM cell size and metal line dimensions.

Therefore, although existing multi-gate semiconductor devices have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1A illustrates a top view device layout of a forksheet semiconductor device according to an embodiment of the present disclosure.

FIG. 1B illustrates a cross-sectional view of the device of FIG. 1A cut along the lines B-B′.

FIG. 1C illustrates a cross-sectional view of the device of FIG. 1A cut along the lines C-C′.

FIG. 2A illustrates a top view device layout of a forksheet semiconductor device according to another embodiment of the present disclosure.

FIG. 2B illustrates a cross-sectional view of the device of FIG. 2A cut along the lines B-B′.

FIG. 2C illustrates a cross-sectional view of the device of FIG. 2A cut along the lines C-C′.

FIG. 3A illustrates a top view device layout of a forksheet semiconductor device according to another embodiment of the present disclosure.

FIG. 3B illustrates a cross-sectional view of the device of FIG. 3A cut along the lines D-D′.

FIG. 3C illustrates a cross-sectional view of the device of FIG. 3A cut along the lines E-E′.

FIG. 4A illustrates a top view device layout of a forksheet semiconductor device according to another embodiment of the present disclosure.

FIG. 4B illustrates a cross-sectional view of the device of FIG. 4A cut along the lines F-F′.

FIG. 5A illustrates a top view SRAM device layout according to an embodiment of the present disclosure.

FIG. 5B illustrates additional features to the top view SRAM device layout 500 of FIG. 5A, according to an embodiment of the present disclosure.

FIG. 6A illustrates a portion of the SRAM device layout as shown in FIG. 5.

FIG. 6B illustrates a cross-sectional view of the portion of the device layout in FIG. 6A cut along the lines G-G′.

FIG. 6C illustrates a cross-sectional view of the portion of the device layout in FIG. 6A cut along the lines H-H′.

FIG. 7A illustrates a portion of a top view SRAM device layout according to another embodiment of the present disclosure.

FIG. 7B illustrates a cross-sectional view of the portion of the SRAM device layout in FIG. 7A cut along the lines G-G′.

FIG. 7C illustrates a cross-sectional view of the portion of the SRAM device layout in FIG. 7A cut along the lines H-H′.

FIG. 8A illustrates a portion of a top view SRAM device layout according to another embodiment of the present disclosure.

FIG. 8B illustrates a cross-sectional view of the portion of the SRAM device layout in FIG. 8A cut along the lines G-G′.

FIG. 8C illustrates a cross-sectional view of the portion of the SRAM device layout in FIG. 8A cut along the lines H-H′.

FIG. 9 illustrates a top view SRAM device layout according to another embodiment of the present disclosure.

FIG. 10A illustrates a portion of the SRAM device layout shown in FIG. 9.

FIG. 10B illustrates a cross-sectional view of the portion of the device layout in FIG. 10A cut along the lines G-G′.

FIG. 10C illustrates a cross-sectional view of the portion of the device layout in FIG. 10A cut along the lines H-H′.

FIG. 11A illustrates a portion of a top view SRAM device layout according to another embodiment of the present disclosure.

FIG. 11B illustrates a cross-sectional view of the portion of the SRAM device layout in FIG. 11A cut along the lines G-G′.

FIG. 11C illustrates a cross-sectional view of the portion of the SRAM device layout in FIG. 11A cut along the lines H-H′.

FIG. 12A illustrates a portion of a top view SRAM device layout according to another embodiment of the present disclosure.

FIG. 12B illustrates a cross-sectional view of the portion of the SRAM device layout in FIG. 12A cut along the lines G-G′.

FIG. 12C illustrates a cross-sectional view of the portion of the SRAM device layout in FIG. 12A cut along the lines H-H′.

FIGS. 13A-13B illustrate metal gate interconnects and gate vias according to an embodiment of the present disclosure.

FIGS. 14-15 illustrate a flow chart of a method of forming metal gate interconnects and vias according to an embodiment of the present disclosure.

FIGS. 16-30 illustrate cross-sectional views of a semiconductor device at intermediate stages of fabrication and processed in accordance with the method of FIGS. 14-15 according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” may encompass the dimension range from 4.5 nm to 5.5 nm.

The present disclosure relates to semiconductor devices having metal gate interconnects. Particularly, the present disclosure is directed to metal gate interconnects that land on metal gates and provide intermediate interconnections to metal gate vias or source/drain contacts (in cases of shared butted contacts). The metal gate interconnects may be implemented in multi-gate semiconductor devices such as fin field-effect-transistors (FETs) and gate-all-around (GAA) FETs, including GAA nanosheet FETs and GAA forksheet FETs. In a forksheet FET, the metal gate interconnect allows reduction in metal gate height even if the metal gate interconnect lands on a forksheet dielectric wall. The metal gate interconnect also allows for lower resistance of the gate vias by lowering the aspect ratio of the gate vias and allowing for optimized metal selection and formation. In a static random access memory (SRAM) device, the metal gate interconnect may act as the shared butted contact between gate and source/drain contacts. This allows for the reduction of SRAM cell size and the enlargement of metal bit line dimensions to improve read/write margins. Still further, the incorporation of the metal gate interconnect allows for simultaneous metal growth of gate vias and source/drain vias, thereby simplifying the process for forming the semiconductor device.

GAA FETs refer to transistors having gate stacks (gate electrodes and gate dielectric layers) surrounding transistor channels, such as vertically-stacked gate-all-around horizontal nanowire or nanosheet MOSFET devices. Embodiments shown in the present disclosure include GAA FETs such as nanosheet FETs and forksheet FETs, but the present disclosure is not limited thereto. For example, the present disclosure may be implemented with fin FETs. Those of ordinary skill in the art should appreciate that they may readily use the present disclosure as a basis for designing or modifying other structures for carrying out the same purposes and/or achieving the same advantages of the embodiments introduced herein.

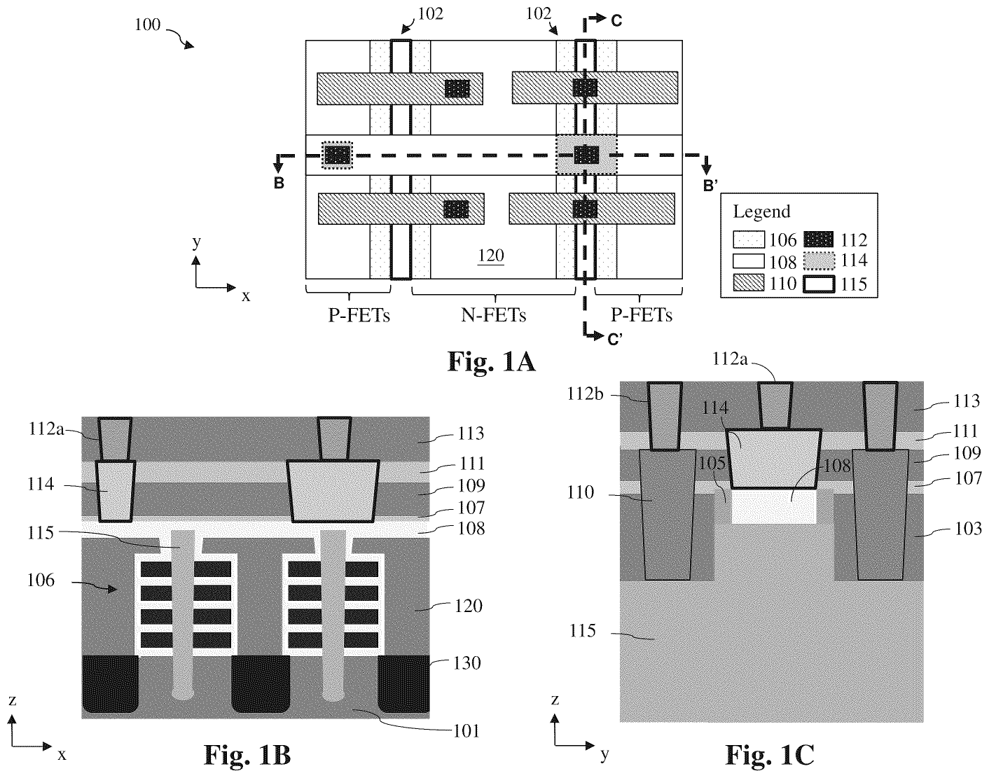

FIG. 1A illustrates a top view device layout of a forksheet semiconductor device 100 according to an embodiment of the present disclosure. The forksheet semiconductor device 100 include two forksheet FETs 102. Each forksheet FET 102 includes an active region 106 and a dielectric wall 115 separating the active region 106 into two portions. As shown, the two portions are part of different doped regions (p-type and n-type). For example, one portion includes P-FETs and the other portion includes N-FETs. The two portions are separated by the dielectric wall 115. In other embodiments, the two portions may be of the same doped type. The two forksheet FETs 102 are separated from each other by an interlayer dielectric (ILD) layer 120. The forksheet FETs 102 extend lengthwise along the y direction. A gate structure 108 is disposed over each of the forksheet FETs 102, and the gate structure 108 extends lengthwise along the x direction. Portions of the forksheet FETs 102 under the gate structure 108 define channel regions, and portions adjacent to the channel regions define source/drain (S/D) regions having S/D features. S/D contacts 110 are disposed over the S/D regions of the forksheet FETs 102 and they electrically connect to respective S/D features. Metal gate interconnects 114 land on the gate structure 108. Several vias 112 land on either the metal gate interconnects 114 or on the S/D contacts 110. For example, gate vias 112a may land on metal gate interconnects 114 and S/D vias 112b may land on S/D contacts 110.

FIG. 1B illustrates a cross-sectional view of the device of FIG. 1A cut along the lines B-B′. In this view, each active region 106 includes a stack of semiconductor layers protruding from a substrate 101 and protruding above a top surface of isolation features 130. The dielectric walls 115 separate each stack of semiconductor layers into two portions and may extend below a top surface of the substrate 101 and below the top surface of isolation features 130. The dielectric walls 115 and the stack of semiconductor layers of the active region 106 each are surrounded by the gate structure 108. Isolation features 130 are formed in the substrate 101 surrounding and defining active regions 106. Along with the ILD layer 120, the isolation features 130 isolate the active regions 106 of the forksheet FETs 102 from each other.

Still referring to FIG. 1B, two metal gate interconnects 114 directly interface the metal gate structure 108. Two gate vias 112a land on the two respective metal gate interconnects 114. The gate vias 112a may have a smaller dimension than the metal gate interconnects 114. In this embodiment, one of the metal gate interconnects 114 lands away from a dielectric wall 115 at an offset in the x direction. The other metal gate interconnect 114 has portions directly landing above a dielectric wall 115. In some embodiments, as shown here, metal gate interconnect 114 that lands directly above a dielectric wall 115 has a larger dimension in the x direction than metal gate interconnects 114 that land away from the dielectric walls in the x direction. This way, appropriate electrical connection between gate and gate vias 112a are ensured even if the metal gate interconnects 114 do not have the best electrical connection with the metal gate 108 in the space directly between the dielectric wall 115 and the gate interconnect 114 (due to a smaller metal gate height in the z direction in this space). Having a wider metal gate interconnect 114 provides electrical connection at other regions of the metal gate structure not directly above the dielectric wall 115.

Still referring to FIG. 1B, in this embodiment, the metal gate interconnects 114 are embedded and isolated from each other by an etch stop layer 107, a dielectric layer 109 over the etch stop layer 107, and an etch stop layer 111 over the dielectric layer 109. Note that other configurations of etch stop layers and dielectric layers are possible. The gate vias 112a are embedded in another dielectric layer 113 above the etch stop layer 111 and above the metal gate interconnects 114.

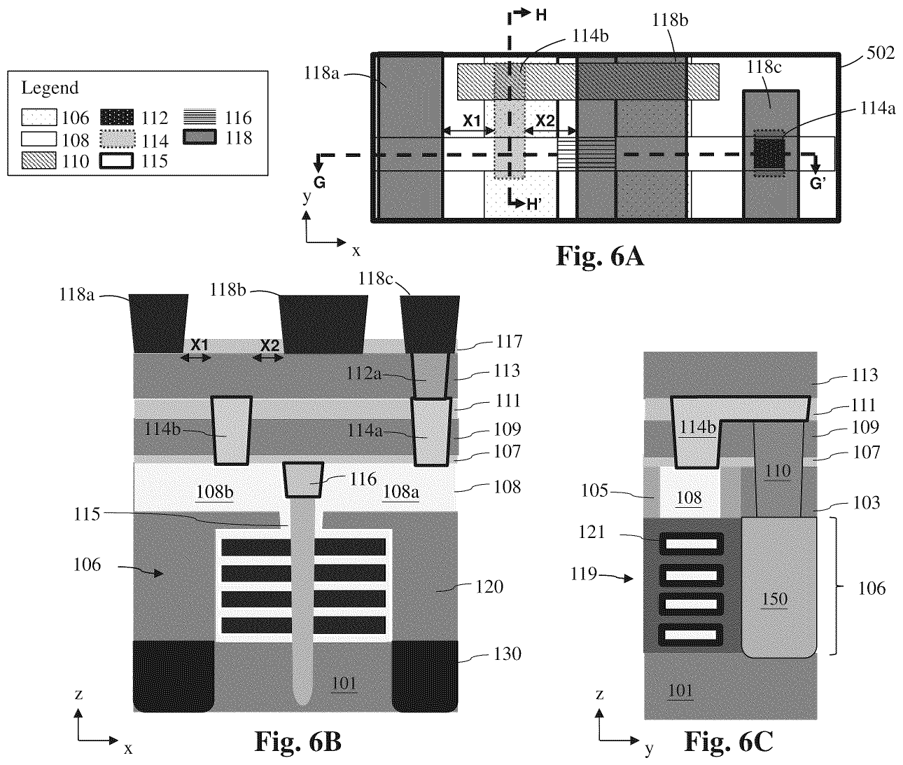

FIG. 1C illustrates a cross-sectional view of the device of FIG. 1A cut along the lines C-C′ through a dielectric wall 115 and through respective vias 112a and 112b over the metal gate structure 108 and S/D contacts 110. As shown in FIG. 1C, portions of the dielectric wall 115 adjacent to the metal gate structure 108 are lower in the z direction. In these portions, the dielectric wall 115 is in the S/D regions of the forksheet FET active regions 106, where the dielectric wall 115 has been etched to a lower height along with the etching and growing of S/D epitaxial features in the S/D regions. S/D contacts 110 are disposed over and in contact with SD epitaxial features (not shown in this view but shown for example in FIG. 6C), but they also land on the dielectric wall 115. The metal gate structure 108 lands on the higher portion of the dielectric wall 115 and may include gate spacers 105 on its sidewalls. S/D vias 112b directly land on each of the S/D contacts 110, while a metal gate interconnect 114 is disposed between the metal gate structure 108 and the gate via 112a that lands on top of the metal gate interconnect 114. In some embodiments, the metal gate interconnect 114 has a greater dimension than the gate structure 108 and vias 112a and 112b in the y direction.

Still referring to FIG. 1C, as shown, the top surface of the S/D contacts 110 is higher than the top surface of the metal gate structure 108 in the z direction. And the top surface of the metal gate interconnect 114 is higher than the top surface of the S/D contacts. As such, the gate via 112a may have a smaller height than the S/D vias 112b. The metal gate interconnect 114 thus reduces the aspect ratio of the gate via 112a for seamless metal fill.

Still referring to FIG. 1C, in this embodiment, the S/D contacts 110 are embedded and isolated from other features by a dielectric layer 103, with the etch stop layer 107 over the dielectric layer 103, and the dielectric layer 109 over the etch stop layer 107. The S/D vias 112b are embedded and isolated from other features by the etch stop layer 111 over the dielectric layer 109 and the dielectric layer 113 over the etch stop layer 111. Note that other configurations of etch stop layers and dielectric layers are possible.

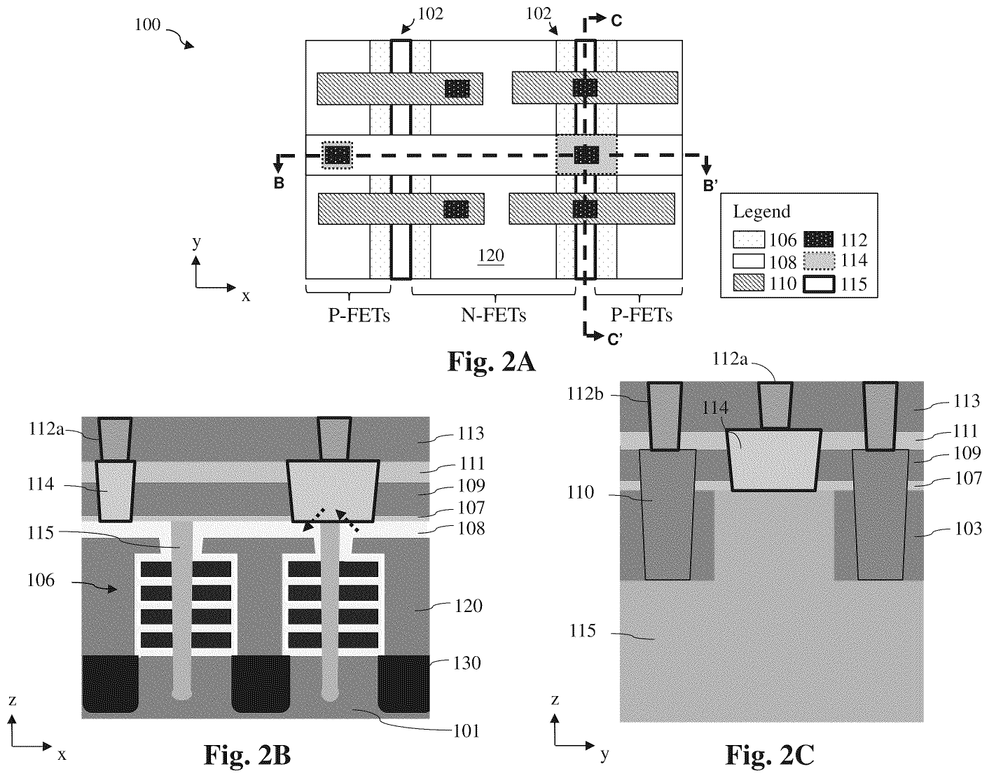

FIG. 2A illustrates a top view device layout of a forksheet semiconductor device according to another embodiment of the present disclosure. FIGS. 2B and 2C illustrate cross-sectional views of the device of FIG. 2A cut along the lines B-B′ and C-C′, respectively. FIGS. 2A-2C are substantially similar to the respective FIGS. 1A-1C. For the sake of brevity, similar configurations and connections will not be repeated here. The difference is that in FIGS. 2A-2C, the gate structure 108 does not contact top portions of the dielectric walls 115. Therefore, portions of the gate structure 108 are electrically isolated from each other by the dielectric walls 115 due to the gate structure 108 not being tall enough in the z direction. In this embodiment, the dielectric walls 115 may also act as cut metal gate features. As shown, the metal gate interconnect 114 that is directly above a dielectric wall 115 directly contacts the dielectric wall. Thus, along the y direction, as shown in FIG. 2C, the metal gate interconnect 114 only lands on the dielectric wall 115 and not on the gate structure 108, since no portion of the gate structure 108 is present in this view. However, as shown in FIG. 2B, because the metal gate interconnect 114 is wider than the dielectric wall in the x direction, the metal gate interconnect still lands on the metal gate structure 108, providing electrical interconnection between portions of the metal gate structure 108 separated by the dielectric wall 115 (shown by the dashed arrows). In this embodiment, the metal gate structure 108 may have a lower height than the embodiment shown in FIGS. 1A-1C.

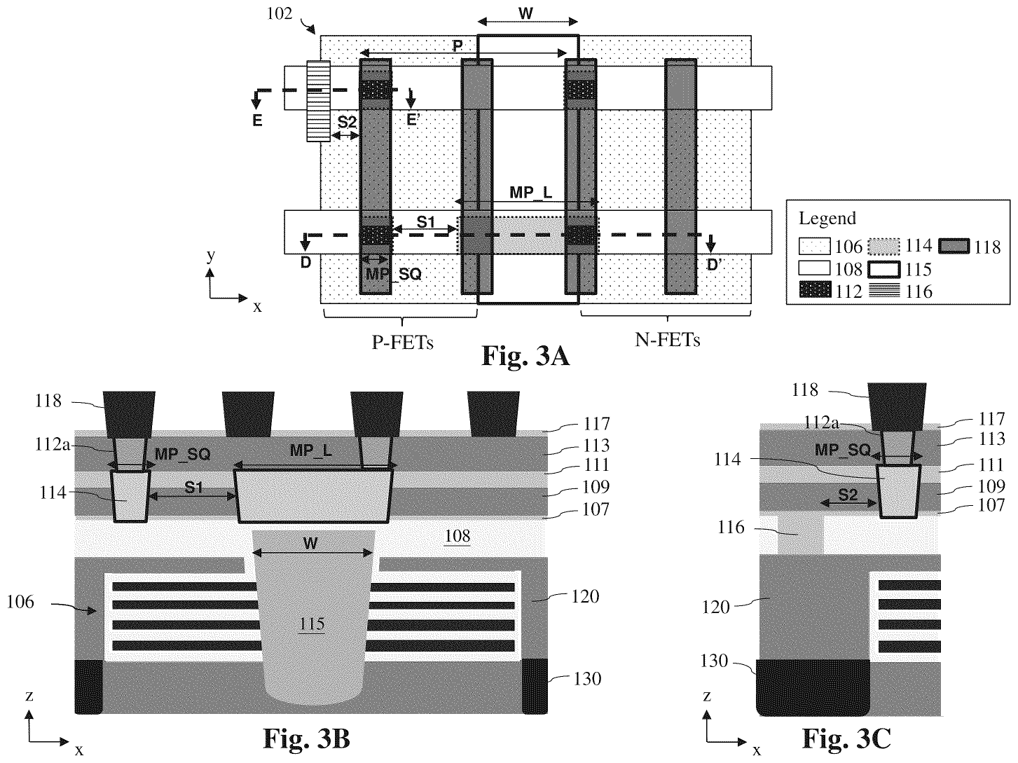

FIG. 3A illustrates a top view device layout of a forksheet semiconductor device according to another embodiment of the present disclosure. FIG. 3A shows a single forksheet device 102 having an active region 106 for P-FETs and an active region 106 for N-FETs separated by a dielectric wall 115. Metal gate structures 108 extend lengthwise along the x direction over the active regions 106 and the dielectric wall 115. Metal gate interconnects 114 land on the respective metal gate structures 108. Vias 112 land on the respective metal gate interconnects 114. The vias 112 connect the metal gate interconnects to metal lines 118 above, which extend lengthwise along the y direction. A cut metal gate feature 116 is shown to the left of the leftmost metal line 118. The cut metal gate feature 116 cuts the top metal gate feature 108 into two portions, thereby electrically isolating the two portions.

Still referring to FIG. 3A, four metal lines 118 are disposed over the forksheet device 102. Two of the metal lines 118 are disposed along edges of the dielectric wall along the y direction. Each of the four metal lines 118 are about equally spaced apart in the x direction. A dimension P is the pitch between two metal lines 118 with a metal line in between the two metal lines 118. A width W is the width of the dielectric wall 115 along the x direction. A distance MP_SQ is the length of a square-shaped metal gate interconnect 114 along the x direction. A distance MP_L is the length of a long metal gate interconnect 114 along the x direction. A distance S1 is a distance between two metal gate interconnects 114 along the x direction. And a distance S2 is a distance between the cut metal gate feature 116 and one of the metal gate interconnects 114 along the x direction.

FIG. 3B illustrates a cross-sectional view of the device of FIG. 3A cut along the lines D-D′. The labels W, MP_SQ, MP_L, and S1 correspond to the same labels shown in FIG. 3A. As shown, along the x direction, the length MP_L of the long metal gate interconnect 114 is greater than the width W of the dielectric wall 115. In some embodiments, the ratio of MP_L to W is about 1.2. Along the x direction, the length MP_L of the long metal gate interconnect 114 is greater than the length MP_SQ of the square-shaped metal gate interconnect 114. In some embodiments, the ratio of MP_L to MP_SQ is about 2.5. The square-shaped metal gate interconnect 114 lands away from the dielectric wall 115 at a greater distance than a distance away from the long metal gate interconnect 114. A distance S1 between the square-shaped and long metal gate interconnects 114 should be at a proper distance to prevent a short between the two metal gate interconnects 114. In some embodiments, a ratio between the distance P to S1 is at least about 4.4. Vias 112 land on each of the square-shaped and long metal gate interconnects 114, which connects to respective metal lines 118. The metal lines 118 may either land on vias 112 or on the dielectric layer 113. The metal lines 118 may penetrate through another etch stop layer 117. As shown in this embodiment, only one via 112a lands on top of the long metal gate interconnect 114. However, in other embodiments, another via 112 may also land on the long metal gate interconnect 114. As described above, the extra length of the long metal gate interconnect 114 is to ensure proper electrical connection to the metal gate structure 108 due to the dielectric wall 115. For the sake of brevity, other features and configurations similar to that of FIGS. 1A-1C will not be repeated here.

FIG. 3C illustrates a cross-sectional view of the device of FIG. 3A cut along the lines E-E′. The labels MP_SQ and S2 correspond to the same labels shown in FIG. 3A. In this view, the cut metal gate feature 116 is shown to cut through the metal gate structure 108. The cut metal gate feature 116 may be disposed between the etch stop layer 107 and the ILD layer 120. A distance between a metal gate interconnect 114 and a metal gate cut feature 118 should be at a proper distance to prevent an open between the interconnect 114 and the metal gate structure 108. Therefore, in some embodiments, the distance S2 along the x direction should be one such that a ratio between the distance P to S2 is at least about 7.3. For the sake of brevity, other features and configurations similar to those already recited will not be repeated here.

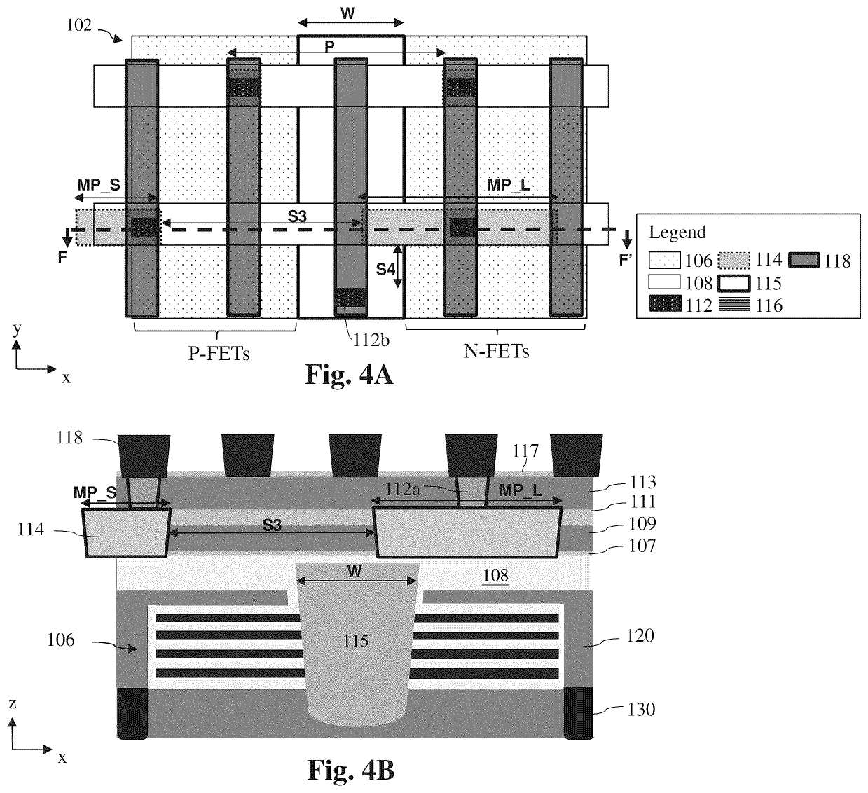

FIG. 4A illustrates a top view device layout of a forksheet semiconductor device according to another embodiment of the present disclosure. FIG. 4A is similar to FIG. 3A and similar features and configurations will not be repeated here for the sake of brevity. In FIG. 4A, there are five metal lines 118 over a single forksheet device 102. A center metal line 118 is disposed directly over a center portion of the dielectric wall 115. A via 112b for S/D feature connections is disposed between the center metal line 118 and a S/D contact 110 (not shown here) over the dielectric wall 115. The other vias 112 are gate vias 112a for metal gate connections between metal gate structures 108 and metal lines 118. The dimensions of W, P, and MP_L correspond to that of the W, P, and MP_L as shown in FIGS. 3A-3C. Additionally, a distance MP_S is the length of a short metal gate interconnect 114 along the x direction. Along the x direction, MP_S has a greater length than MP_SQ (shown in FIG. 3A) but a shorter length than MP_L. A distance S4 is a distance between a metal gate interconnect 114 and a via 112b along the y direction. S4 should be at a proper distance to prevent a short between the metal interconnect 114 and the via 112b due to an overlap between the two features along the x direction. In some embodiments, a ratio between the distance P to S4 is at least about 3.6. S3 is a distance between a long and a short metal gate interconnect 114.

FIG. 4B illustrates a cross-sectional view of the device of FIG. 4A cut along the lines F-F′. The labels W, MP_S, MP_L, and S3 correspond to the same labels shown in FIG. 4A. Along the x direction, the length MP_L of the long metal gate interconnect 114 is greater than the length MP_S of the short metal gate interconnect 114, and the length MP_S of the short metal gate interconnect 114 is greater than the length MP_SQ of the square-shaped metal gate interconnect 114 shown in FIG. 3B. In some embodiments, the ratio of MP_L to MP_S is about 1.5 and the ratio of MP_S to MP_SQ is about 1.5. In some embodiments, the long metal gate interconnect 114 spans directly under portions of three different metal lines 118. A portion of the long metal gate interconnect 114 also span directly above a portion of the dielectric wall 115. The distance S3 between a long and a short metal gate interconnect 114 may be one such that a ratio between the distance P to S3 is greater than about 1.1. Each of the short and long metal gate interconnects 114 connects to a metal line 118 through gate vias 112a. For the sake of brevity, other features and configurations similar to those already recited will not be repeated here.

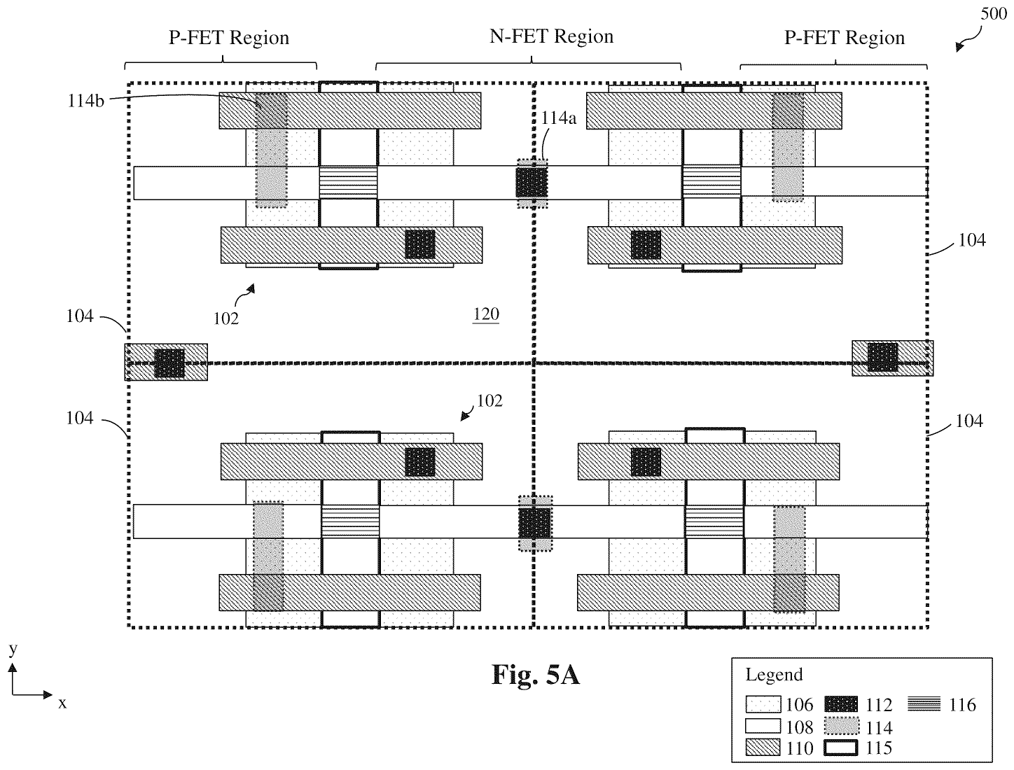

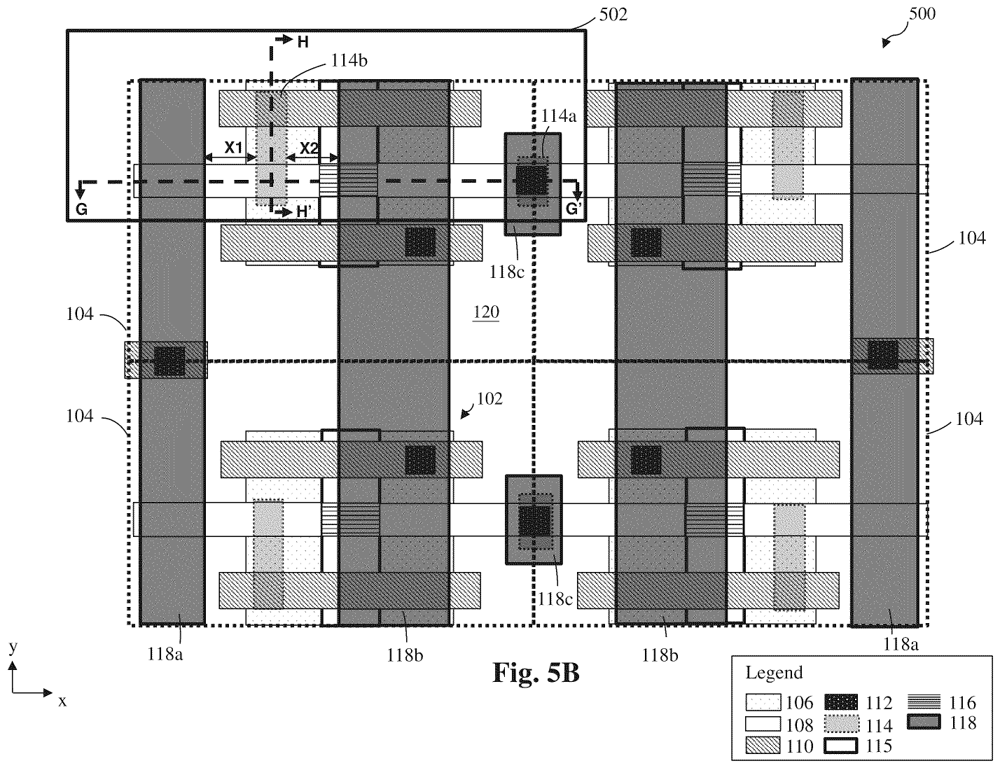

FIG. 5A illustrates a top view SRAM device layout 500 according to an embodiment of the present disclosure. The SRAM device layout 500 includes portions of four different SRAM cells 104 defined by the four dashed cell boundaries. Note that the SRAM device layout 500 only show portions of each of the SRAM cells 104 for purposes of simplicity. Each SRAM cells 104 may include additional components not shown. Further, the SRAM device layout 500 may only show a portion of an SRAM device. As shown, there are P-FET and N-FET regions as part of the SRAM device. In some embodiments, the P-FET regions include pull-up transistors, and the N-FET regions include pull-down and pass-gate transistors of the SRAM device.

Each of the SRAM cells 104 includes a forksheet FET 102 extending lengthwise along the y direction, the forksheet FET 102 having active regions 106 separated by a dielectric wall 115. For each forksheet FET 102, a metal gate structure 108 spans across respective active regions 106 along the x direction, defining a channel region of the active region 106 underneath the gate structure and defining S/D regions of the active region adjacent to the channel region. The metal gate structures 108 have portions separated from each other by cut metal gate features 116 disposed over dielectric walls 115. For each forksheet FET 102, an S/D contact 110 may be disposed over S/D regions of each of the active regions 108. The S/D contacts 110 may span across dielectric walls 115 along the x direction. Each forksheet FET 102 may be separated from each other by an ILD layer 120.

Still referring to FIG. 5A, there may be several metal gate interconnects 114 that land on the metal gate structures 108. Of these, there are metal gate interconnects 114b that act as shared butted contacts, connecting respective metal gate structures 108 to respective S/D contacts 110. There are also metal gate interconnects 114a do not act as shared butted contacts (e.g., the metal gate interconnects 114a on portions of the metal gate structures 108 spanning across cell boundaries). There are several vias 112 that either land on the S/D contacts 110 or the metal gate interconnects 114a. Note that the vias 112 do not land on the metal gate interconnects 114b. The vias 112 connect the respective gate or S/D features to a higher material layer in the z direction.

FIG. 5B illustrates further structures of the device layout 500 of FIG. 5A. For example, FIG. 5B additionally shows several metal lines 118 according to an embodiment of the present disclosure. The metal lines 118 are disposed above the structures illustrated in FIG. 5A in a positive z direction, particularly above the vias 112. These metal lines 118 include metal lines 118a, 118b, and 118c. The metal lines 118a may be power line connections for Vdd, which powers the transistors in the SRAM cells 104. The metal lines 118b may be bit lines or bit line bars for the SRAM cells 104, and the metal lines 118c may be word lines for the SRAM cells 104. In some embodiments, each metal lines 118a connects to a via 112, which connects to a S/D contact 110, which may then connect to S/D epitaxial features that is part of a pull-up transistor (not shown). In some embodiments, each metal lines 118b connects to a via 112, which connects to a S/D contact 110, which may then connect to S/D epitaxial features that is part of a pass-gate transistor (not shown). In some embodiments, each metal lines 118c connects to a via 112, which connects to a metal gate interconnect 114a, which connects to a metal gate structure 108, which may be part of a pass-gate transistor (not shown). Some of the metal lines (e.g., 118a and 118b) may span across cell boundaries along the y direction. Some of the metal lines (e.g., 118c) may span across cell boundaries along the x direction.

Still referring to FIG. 5B, for ease of description in the later figures, a portion of the device layout 500 is boxed in by the box 502. The box 502 includes cross-sectional lines G-G′ and H-H′. The lines G-G′ cuts along the x direction across a metal line 118a, a metal line 118b, and a metal line 188c. The lines G-G′ cuts through the length of a metal gate structure 108 and across metal gate interconnects 114 (including 114a and 114b). The lines G-G′ also cuts through a cut metal gate feature 116 and a via 112. The lines H-H′ cuts along the y direction across a S/D contact 110 and a metal gate structure 108. The lines H-H′ cuts through the length of a metal gate interconnect 114b (butted contact interconnect). As shown, along the x direction, there is a distance x1 between the metal line 118a and the metal gate interconnect 114b and a distance x2 between the metal line 118b and the metal gate interconnect 114b.

FIG. 6A illustrates the box 502 of FIG. 5B. FIGS. 6B and 6C illustrate cross-sectional views of FIG. 6A cut along the lines G-G′ and H-H′, respectively. The labeling convention and description of box 502 has been explained with respect to FIG. 5B and will not be recited here again.

As shown in FIG. 6B, active regions 106 of a forksheet FET protrudes above a substrate 101. The active regions 106 include a stack of semiconductor layers separated by a dielectric wall 115. The dielectric wall 115 may extend below a top surface of the substrate 101. The dielectric wall 115 and the stack of semiconductor layers of the active regions 106 are surrounded by a metal gate structure 108. An ILD layer 120 surrounds a portion of the metal gate structure 108 that surrounds the active regions 106. Another portion of the metal gate structure is disposed above a top surface of the ILD layer 120. Isolation features 130 are embedded in the substrate 101 and between active regions 106. The isolation features 130 and the ILD layer 120 isolate the active regions 106 of the forksheet FETs 102 from other forksheet FETs (not shown).

Still referring to FIG. 6B, the metal gate structure 108 is separated into two electrically isolated gate regions 108a and 108b by a cut metal feature 116. A metal gate interconnect 114a lands on and directly interfaces one of the isolated gate regions 108a. A gate via 112a lands on the metal gate interconnect 114a. And a metal line 118c lands on the gate via 112a. In this configuration, the electrical connection between metal line 118c and the metal gate structure 108 is achieved by both the metal gate interconnect 114a and the gate via 112a.

Still referring to FIG. 6B, a metal gate interconnect 114b lands on and directly interfaces another one of the isolated gate regions 108b. As shown, no gate via lands on the metal gate interconnect 114b. Instead, a dielectric layer 113 covers the top surface of the metal gate interconnect 114b. Metal lines 118a and 118b are in a same material layer as metal line 118c, but in this cross-sectional view, they land on the dielectric layer 113 instead of any vias 112a or 112b. In this embodiment, along the x direction, metal line 118a is spaced apart from the metal gate interconnect 114b by a distance x1. And along the x direction, metal line 118b is spaced apart from the metal gate interconnect 114b by a distance x2. As such, from a top view, there is no overlap along the x direction between the metal line interconnect 114b and the metal lines 118a and 118b.

Referring to FIG. 6C, the active region 106 includes a channel region 119 under the metal gate structure 108 and S/D features 150 adjacent to the channel region 119. The S/D features may be epitaxial grown and have silicide layers (not shown) on a top surface of the S/D features 150. The channel region 119 includes semiconductor channels wrapped around by gate dielectric layers 121 and by the metal gate structure 108. In some embodiments, there may be inner spacers (not shown) disposed between the metal gate structure and the S/D features 150. Portions of the metal gate structure 108 above the channel region 119 may include gate spacers 105 along its sidewalls. An S/D contact 110 is disposed over and in contact with S/D features 150. And a metal gate interconnect 114b is disposed over and in contact with top surfaces of the metal gate structure 108 and the S/D contact 110. The metal gate interconnect 114b may act as a butted contact that connects gate and S/D portions of different transistors together (e.g., gate of a pull-up transistor connecting to drains of a pull-down transistor, a pass-gate transistor, and another pull-up transistor). As shown, the metal gate interconnect 114b have portions thicker in the z direction that land on the metal gate structure 108 and portions thinner in the z direction that land on the S/D contact 110. The dielectric layer 113 is disposed over both the thicker and thinner portions of the metal gate interconnect 114b.

Still referring to FIG. 6C, in this embodiment, the S/D contacts 110 are embedded and isolated from other features by a dielectric layer 103, the etch stop layer 107 over the dielectric layer 103, and the dielectric layer 109 over the etch stop layer 107. The metal gate interconnect 114b is embedded and isolated from other features by the etch stop layer 107 over the metal gate structure 108, the dielectric layer 109 over the etch stop layer 107, and the etch stop layer 111 over the dielectric layer 109. Note that other configurations of etch stop layers and dielectric layers are possible.

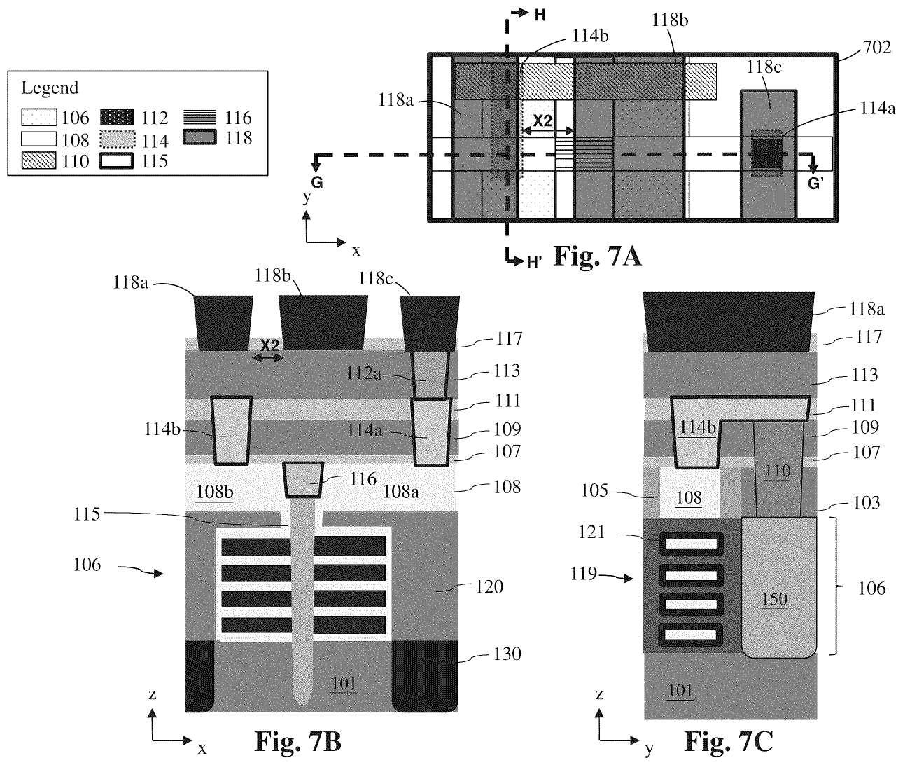

FIGS. 7A-7C illustrate similar features to FIGS. 6A-6C, respectively. For the sake of brevity, the similar features will not be repeated here. FIG. 7A illustrates a box 702, which shows a portion of a SRAM device layout similar to that of box 502 in FIG. 6A. However, box 702 is smaller than box 502 in the x direction, thereby reducing SRAM cell size. This is because in box 702, the metal line 118a is placed closer to the metal line 118b in the x direction. Compared to box 502, there is no distance x1 between the metal line 118a and the metal gate interconnect 114b. In some embodiments, portions of the metal line 118a is directly over the metal gate interconnect 114b. In these embodiments, from a top view, there is overlap along the x direction between the metal line 118a and the metal gate interconnect 114b.

FIGS. 7B and 7C illustrate cross-sectional views of FIG. 7A cut along the lines G-G′ and H-H′, respectively. As shown in FIGS. 7A-7B, the spacing between metal lines 118a and 118b includes the distance x2 but does not include the distance x1. Because of the dielectric layer 113, which is disposed between the metal gate interconnect 114b and the metal line 118a, the metal line 118a may be disposed directly over the metal gate interconnect 114b without undesired shorting issues, thereby allowing for SRAM cell shrinkage. However, to prevent shorting issues between metal lines 118a and 118b, there may still be a distance x2 between the metal line 118b and the metal gate interconnect 114b. FIGS. 7A-7C illustrate the metal line 118a substantially covering the metal gate interconnect 114b. In other embodiments, the metal line 118a may only cover partially or slightly the metal gate interconnect 114b.

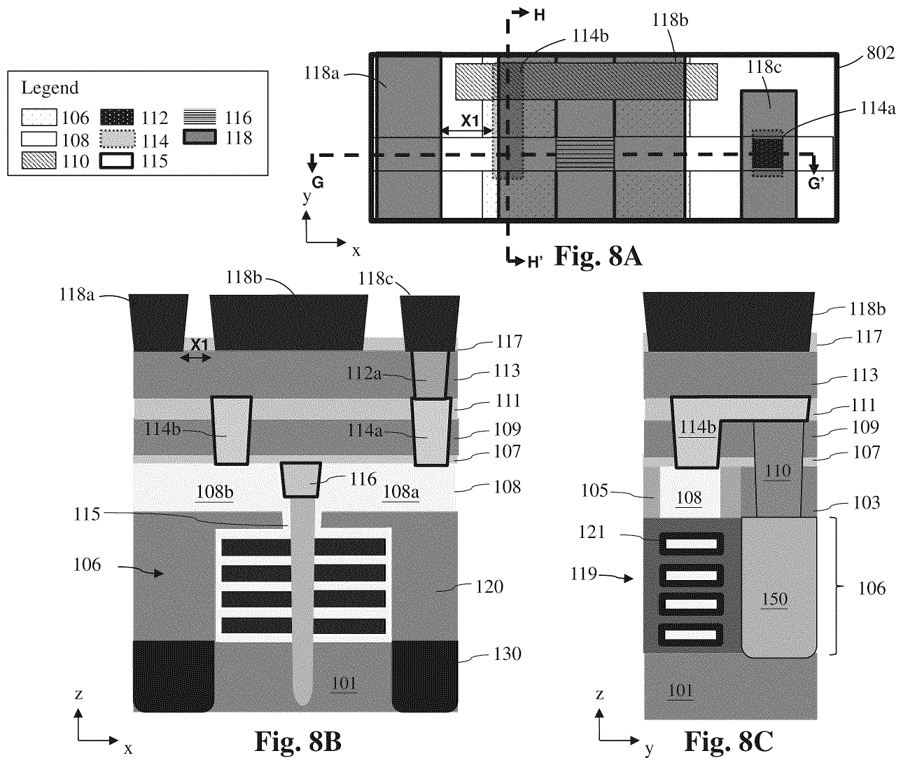

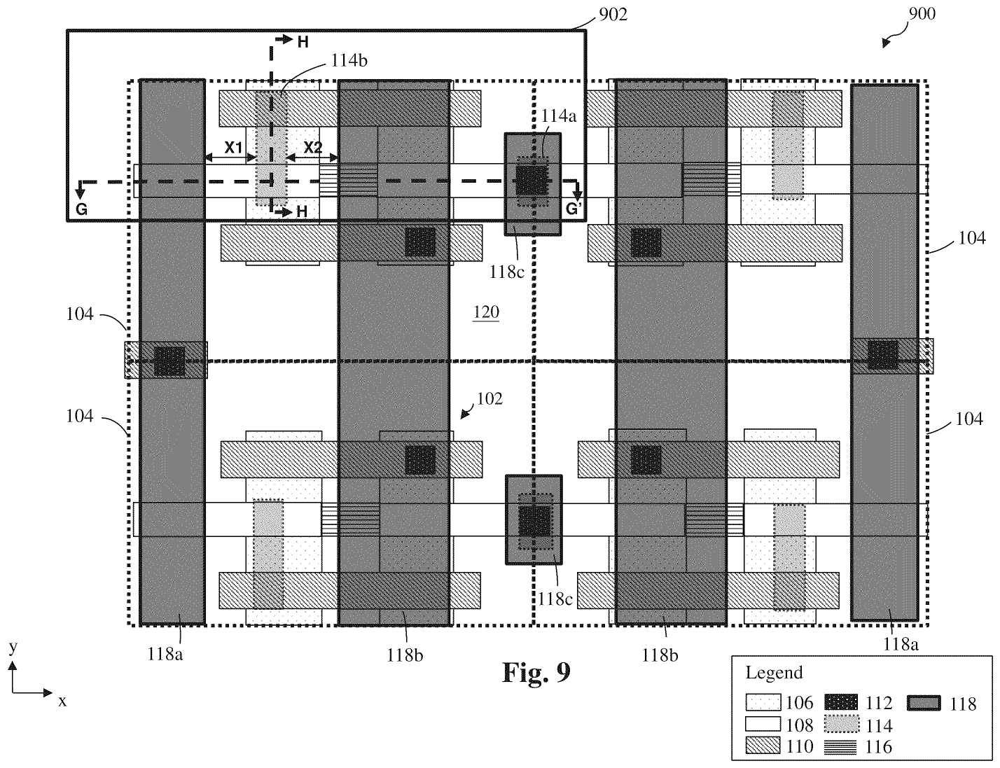

FIGS. 8A-8C illustrate similar features to FIGS. 6A-6C, respectively. For the sake of brevity, the similar features will not be repeated here. FIG. 8A illustrates a box 802, which shows a portion of a SRAM device layout similar to that of box 502 in FIG. 6A. However, the metal line 118b in box 802 is larger in a dimension along the x direction than the metal line 118b in box 502. Metal line 118b may be signal lines such as bit lines or bit line bars. This increase in dimension may improve the speed of the SRAM device in read/write operations. Compared to box 502, there is no distance x2 between the metal line 118b and the metal gate interconnect 114b. In some embodiments, portions of the metal line 118b is directly over the metal gate interconnect 114b. In these embodiments, from a top view, there is overlap along the x direction between the metal line 118b and the metal gate interconnect 114b.

FIGS. 8B and 8C illustrate cross-sectional views of FIG. 8A cut along the lines G-G′ and H-H′, respectively. As shown in FIGS. 8A-8B, the spacing between metal lines 118a and 118b includes the distance x1 but does not include the distance x2. Because of the dielectric layer 113, which is disposed between the metal gate interconnect 114b and the metal line 118b, the metal line 118b may be disposed directly over the metal gate interconnect 114b without undesired shorting issues, thereby allowing for an increased size for metal line 118b. However, to prevent shorting issues between metal lines 118a and 118b, there may still be a distance x1 between the metal line 118a and the metal gate interconnect 114b. FIGS. 8A-8C illustrate the metal line 118b substantially covering the metal gate interconnect 114b. In other embodiments, the metal line 118b may only cover partially or slightly the metal gate interconnect 114b.

FIGS. 7A-7C and 8A-8C illustrate embodiments where either the distance x1 is removed or the distance x2 is removed. In other embodiments, the distance x1 and x2 may both still be present (like in FIGS. 6A-6C), but the distances are varied according to design considerations. For example, x1 may be shortened while x2 remain constant, x2 may be shortened while x1 remain constant, or both x1 and x2 are shortened. Further, when x1 or x2 are shortened, metal lines 118a or 118b may increase in size or the SRAM cell may shrink in size. In further embodiments, a combination of both may occur.

FIG. 9 illustrates a top view SRAM device layout 900 according to another embodiment of the present disclosure. The SRAM device layout 900 is substantially similar to the device layout 500 of FIG. 5B. For the sake of brevity, similar features will not be repeated here. Device layout 900 illustrates separate active regions 106 without a dielectric wall 115. These active regions 106 may be active regions for fin FETs or GAA FETs such as GAA nanosheet FETs. For example, instead of having a dielectric wall 115 separating active regions of a single forksheet FET 102, an ILD layer 120 may be in its place to separate each active regions 106 from each other. A portion of the device layout 900 is boxed in by the box 902. The box 902 includes cross-sectional lines G-G′ and H-H′. The lines G-G′ cuts along the x direction across a metal line 118a, a metal line 118b, and a metal line 188c. The lines G-G′ cuts through the length of a metal gate structure 108 and across metal gate interconnects 114 (including 114a and 114b). The lines G-G′ also cuts through a cut metal gate feature 116 and a via 112. The lines H-H′ cuts along the y direction across a S/D contact 110 and a metal gate structure 108. The lines H-H′ cuts through the length of a metal gate interconnect 114b (butted contact interconnect). As shown, along the x direction, there is a distance x1 between the metal line 118a and the metal gate interconnect 114b and a distance x2 between the metal line 118b and the metal gate interconnect 114b.

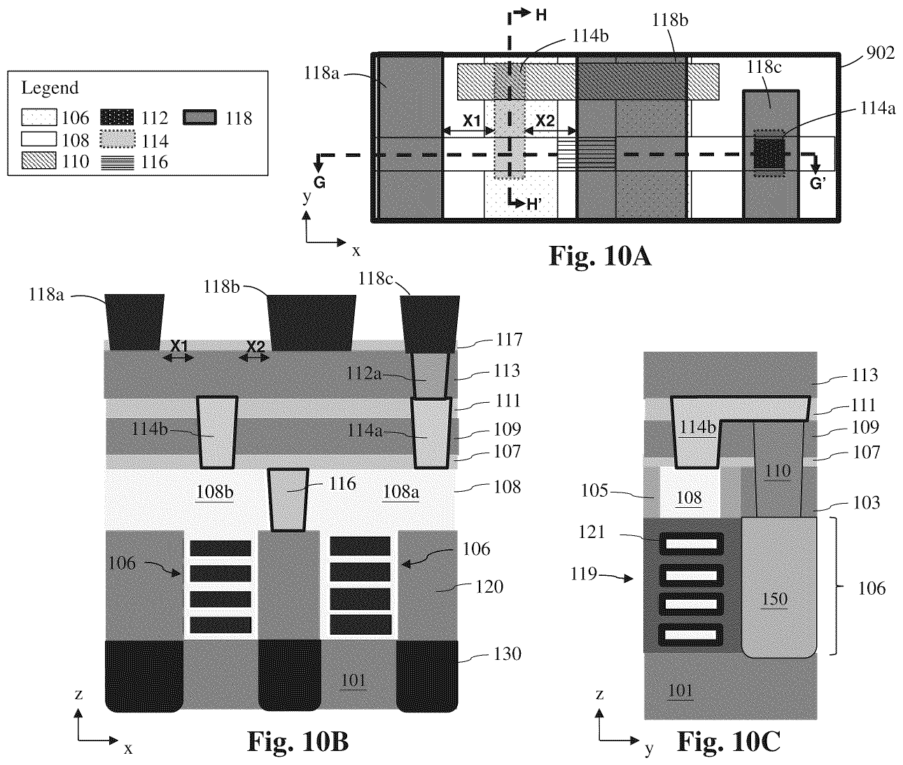

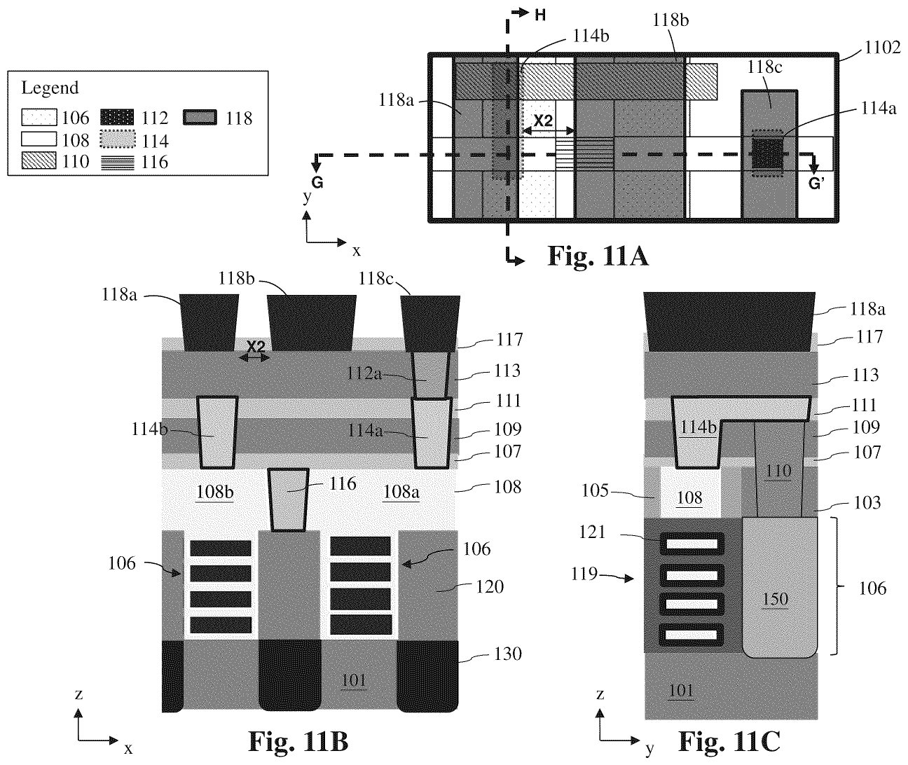

FIG. 10A illustrates the box 902 of FIG. 9. FIGS. 10B and 10C illustrate cross-sectional views of FIG. 10A cut along the lines G-G′ and H-H′, respectively. FIGS. 10A-10C is substantially similar to FIGS. 6A-6C. For the sake of brevity, the similar features will not be repeated here for the sake of brevity. In FIG. 10B, two distinct active regions 106 are shown, each having a stack of semiconductor layers. The active regions 106 are isolated from each other by an ILD layer 120 and isolation features 130 below the ILD layer 120. The stacks of semiconductor layers of each of the active regions 106 are surrounded by a metal gate structure 108. The metal gate structure 108 is separated into two electrically isolated gate regions 108a and 108b by a cut metal feature 116. As shown, the metal gate interconnects 114a and 114b can be similarly implemented as they had been implemented in FIGS. 6A-6C.

FIG. 11A illustrates a box 1102, which shows a portion of a SRAM device layout similar to that of box 902 in FIG. 9. However, box 1102 is smaller than box 902 in the x direction, thereby reducing SRAM cell size. This is because in box 1102, the metal line 118a is placed closer to the metal line 118b in the x direction. Compared to box 902, there is no distance x1 between the metal line 118a and the metal gate interconnect 114b. In some embodiments, portions of the metal line 118a is directly over the metal gate interconnect 114b. In these embodiments, from a top view, there is overlap along the x direction between the metal line 118a and the metal gate interconnect 114b. FIGS. 11B-11C illustrate cross-sectional views of FIG. 11A. FIGS. 11B-11C are substantially similar to FIGS. 7A-7C. For the sake of brevity, the similar features will not be repeated here. As shown, the metal gate interconnects 114a and 114b can be similarly implemented as they had been implemented in FIGS. 7A-7C.

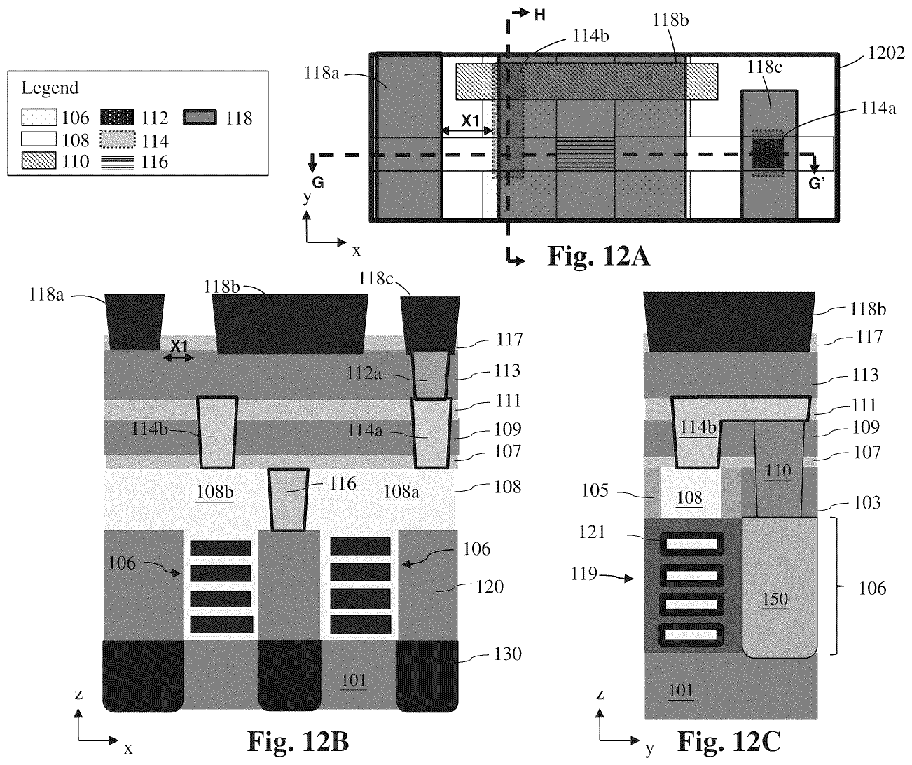

FIG. 12A illustrates a box 1202, which shows a portion of a SRAM device layout similar to that of box 902 in FIG. 9. However, the metal line 118b in box 1202 is larger in a dimension along the x direction than the metal line 118b in box 902. Metal line 118b may be signal lines such as bit lines or bit line bars. This increase in dimension may improve the speed of the SRAM device in read/write operations. Compared to box 902, there is no distance x2 between the metal line 118b and the metal gate interconnect 114b. In some embodiments, portions of the metal line 118b is directly over the metal gate interconnect 114b. In these embodiments, from a top view, there is overlap along the x direction between the metal line 118b and the metal gate interconnect 114b. FIGS. 12B-12C illustrate cross-sectional views of FIG. 12A. FIGS. 12B-12C are substantially similar to FIGS. 8A-8C. For the sake of brevity, the similar features will not be repeated here. As shown, the metal gate interconnects 114a and 114b can be similarly implemented as they had been implemented in FIGS. 8A-8C.

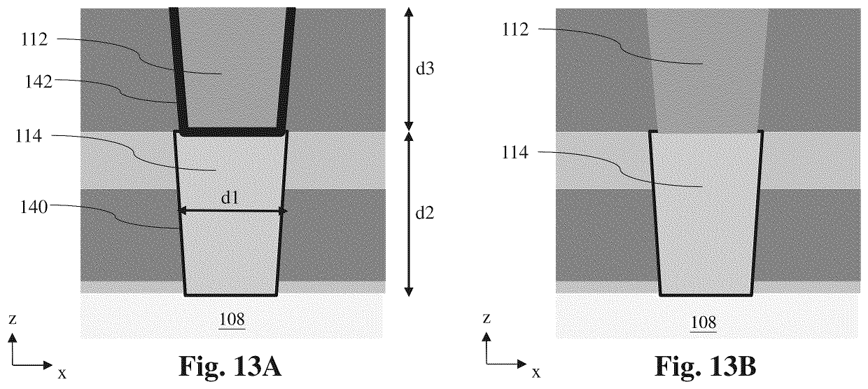

FIGS. 13A-13B illustrate metal gate interconnects 114 and vias 112 according to an embodiment of the present disclosure. The metal gate interconnects 114 may include the metal gate interconnects 114a or 114b. The vias 112 may include the vias 112a or 112b. As shown, the metal gate interconnects 114 land on metal gate structures 108. A metal gate interconnect 114 may have a width d1 along the x direction and a height d2 along the z direction. In some embodiments, the ratio of d2 to d1 (the aspect ratio of the metal gate interconnect) is about 2.5 or less. Further, a via 112 may have a height d3 along the z direction. In some embodiments, the ratio of d2+d3 to d1 (the aspect ratio of metal features between a gate metal gate structure 108 and a metal line above (not shown)) is about 4.5 or less. Generally, a smaller aspect ratio is desirable for improving the filling of metal materials and to avoid seams or voids in the metal fill. By having no voids or minimal voids in the metal gate interconnects 114, the vias 112 that land on top of the metal gate interconnects 114 will make better electrical contact with the metal gate structure 108 and the vias 112 may also result in no voids or minimal voids. In an embodiment, the metal gate interconnect 114 may include a metal fill material comprising tungsten (W) formed by CVD. In other embodiments, the metal fill material may comprise other metals such as cobalt (Co), molybdenum (Mo), or ruthenium (Ru), and may be formed by CVD, PVD, ALD, plating, or other suitable processes. The metal fill material may be surrounded by a barrier layer 140 such that the metal fill material is enclosed within the barrier layer 140. The barrier layer 140 may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes.

Referring to the embodiment shown in FIG. 13A, the via 112 may include a metal fill material comprising tungsten (W) formed by CVD isotropic growth. In other embodiments, the metal fill material may comprise other metals such as cobalt (Co), molybdenum (Mo), or ruthenium (Ru), and may be formed by CVD, PVD, ALD, plating, or other suitable processes. The metal fill material of the via 112 may be surrounded by a barrier layer 142 such that the metal fill material is enclosed within the barrier layer 142. The barrier layer 142 may be similar to the barrier layer 140. In an isotropic growth scheme, the fill metal is grown from bottom and side surfaces of the barrier layer 140.

Referring to the embodiment shown in FIG. 13B, the via 112 may include a metal fill material comprising tungsten (W) or molybdenum (Mo) formed by bottom up selective growth. In this case, the metal fill material is not surrounded by a barrier layer. In a bottom up selective growth scheme, the fill metal is substantially grown in the z direction from a top surface of the metal gate interconnect 114 without much growth in the x or y direction.

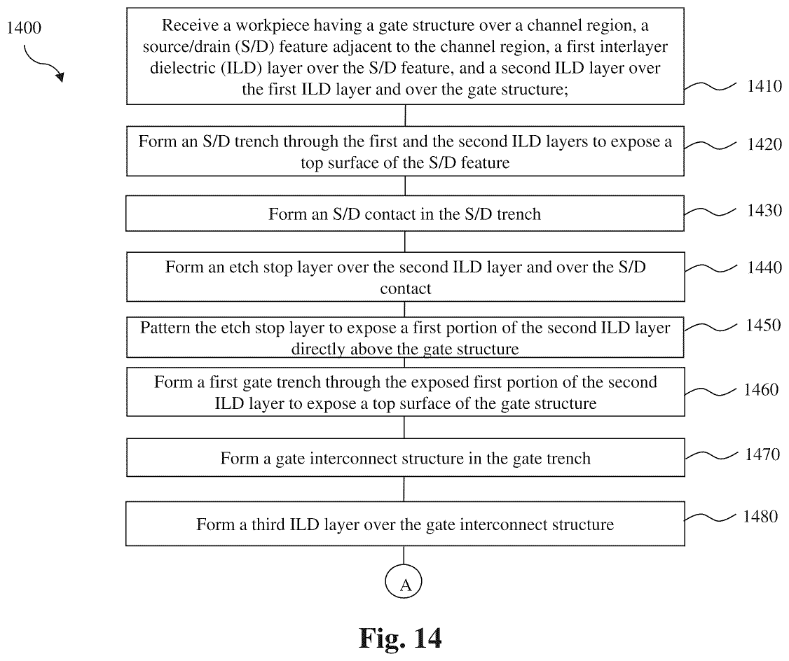

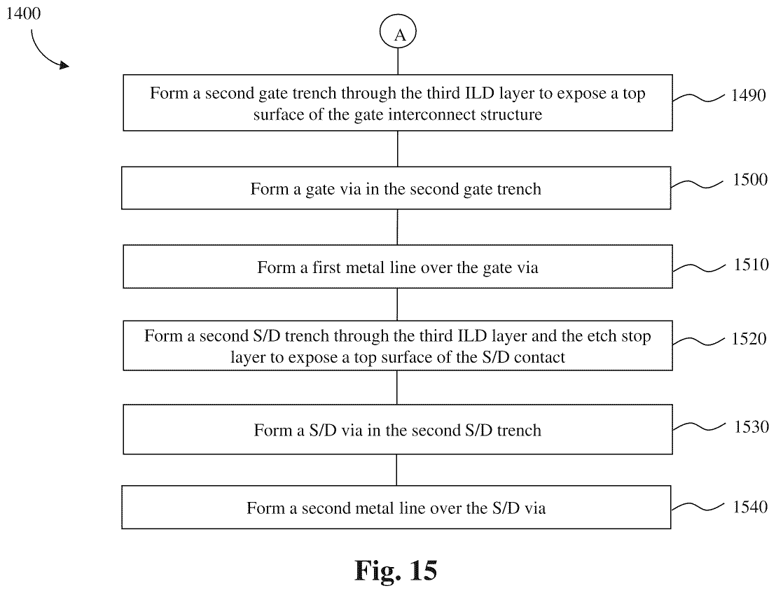

FIGS. 14-15 illustrate a flow chart of a method 1400 of forming metal gate interconnects 114 and vias 112 according to an embodiment of the present disclosure. The method 1400 is briefly described below. At operation 1410, the method 1400 receives or is provided with a workpiece that includes a gate structure over a channel region, an S/D feature adjacent to the channel region, a first ILD layer over the S/D feature, and a second ILD layer over the first ILD layer and over the gate structure. The channel region may be a channel region for a fin FET, a nanosheet FET, a nanowire or nanosheet FET, or other types of multi-gate FETs. The channel region may be part of an active region protruding from a substrate. At operation 1420, the method 1400 forms an S/D trench through the first and the second ILD layers to expose a top surface of the S/D features. At operation 1430, the method 1400 forms an S/D contact in the S/D trench. At operation 1440, the method 1400 forms an etch stop layer over the second ILD layer and over the S/D contact. At operation 1450, the method 1400 patterns the etch stop layer to expose a first portion of the second ILD layer directly above the gate structure. At operation 1460, the method 1400 forms a first gate trench through the exposed first portion of the second ILD layer to expose a top surface of the gate structure. At operation 1470, the method 1400 forms a gate interconnect structure in the gate trench. At operation 1480, the method 1400 forms a third ILD layer over the interconnect structure. At operation 1490, the method 1400 forms a second gate trench through the third ILD layer to expose a top surface of the gate interconnect structure. At operation 1500, the method 1400 forms a gate via in the second gate trench. At operation 1510, the method 1400 forms a first metal line over the gate via. At operation 1520, the method 1400 forms a second S/D trench through the third ILD layer and the etch stop layer to expose a top surface of the S/D contact. At operation 1530, the method 1400 forms a S/D via in the second S/D trench. At operation 1540, the method 1400 forms a second metal line over the S/D via. The method 1400 may perform further steps to complete fabrication of a semiconductor device. Additional processing is contemplated by the present disclosure. Additional operations can be provided before, during, and after method 1400, and some of the operations described can be moved, replaced, or eliminated for additional embodiments of method 1400.

Embodiments of the method 1400 can be applied to SRAM devices, logic devices, and other devices, particularly when having better gate contact is of a concern. Embodiments of the method 1400 can be readily integrated into existing manufacturing flow to simplify process flow while improving device performance.

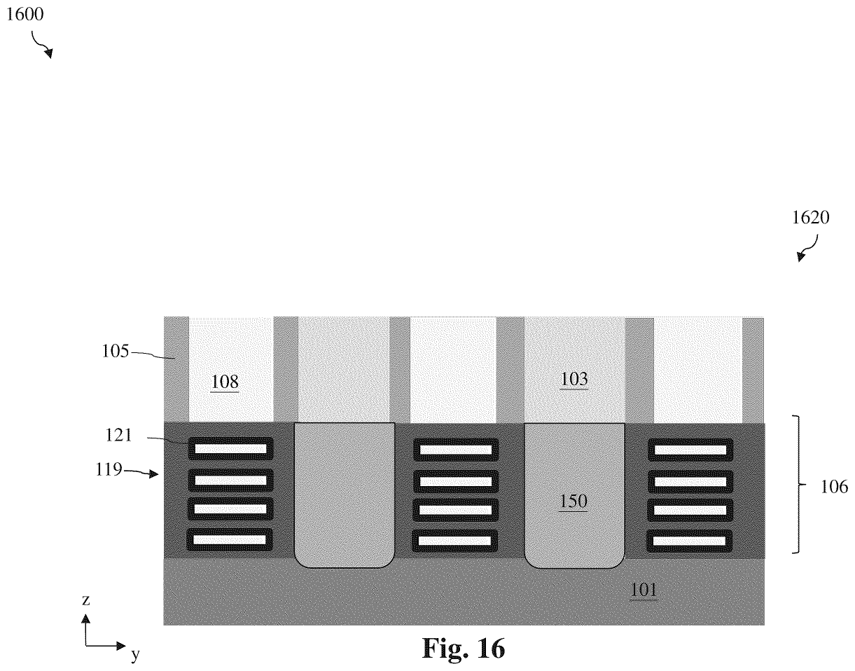

Method 1400 is further described below in conjunction with FIGS. 16-30, which illustrate cross-sectional views of a semiconductor device 1600 at intermediate stages of fabrication and processed according to an embodiment of the present disclosure. In some embodiments, the device 1600 is a portion of an IC chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs (including forksheet FETs), nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In some embodiments, the device 1600 is included in a non-volatile memory, such as a non-volatile random access memory (NVRAM), a flash memory, an electrically erasable programmable read only memory (EEPROM), an electrically programmable read-only memory (EPROM), other suitable memory type, or combinations thereof. FIGS. 16-30 have been simplified for the sake of clarity to better understand the inventive concepts of the present disclosure. Additional features can be added in the device 1600, and some of the features described below can be replaced, modified, or eliminated in other embodiments of the device 1600.

At operation 1410, the method 1400 receives a workpiece 1620 of the device 1600, an embodiment of which is illustrated in FIG. 16. The workpiece 1620 may include a substrate 101. The substrate 101 may protrude above a larger substrate base. Portions of the substrate 101 may be isolated from each other by an isolation feature such as the isolation feature 130 described in prior figures. An active region 106, which includes channel regions 119 and S/D epitaxial features 150 is disposed over the substrate 101. The channel regions 119 may include a stack of semiconductor layers wrapped around by a gate dielectric layer 121 and by a gate structure 108. Gate structures 108 are disposed over each of the channel regions 119. Gate spacers 105 may be disposed along sidewalls of the gate structure 108 above the channel region 119. A dielectric layer 103 is disposed over the S/D features 150 and between gate spacers 105. The dielectric layer 103 may be an interlayer dielectric (ILD) layer comprising tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, and/or other suitable dielectric materials. The ILD layer 103 may be formed by PECVD (plasma enhanced CVD), FCVD (flowable CVD), or other suitable methods. Top surfaces of the gate spacers 105, gate structure 108, and dielectric layer 103 are planarized.

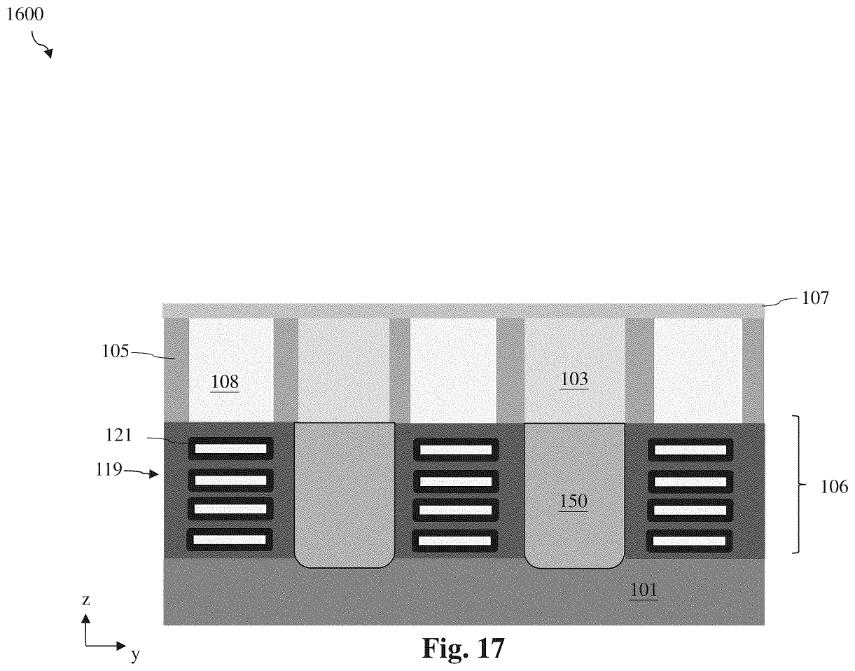

Still referring to operation 1410 but in reference to FIG. 17, the method 1400 may include depositing an etch stop layer 107 over the workpiece 1620 of FIG. 16. The etch stop layer is of a different material composition than the dielectric layer 103. The etch stop layer 107 may include silicon nitride, silicon oxynitride, or other suitable materials.

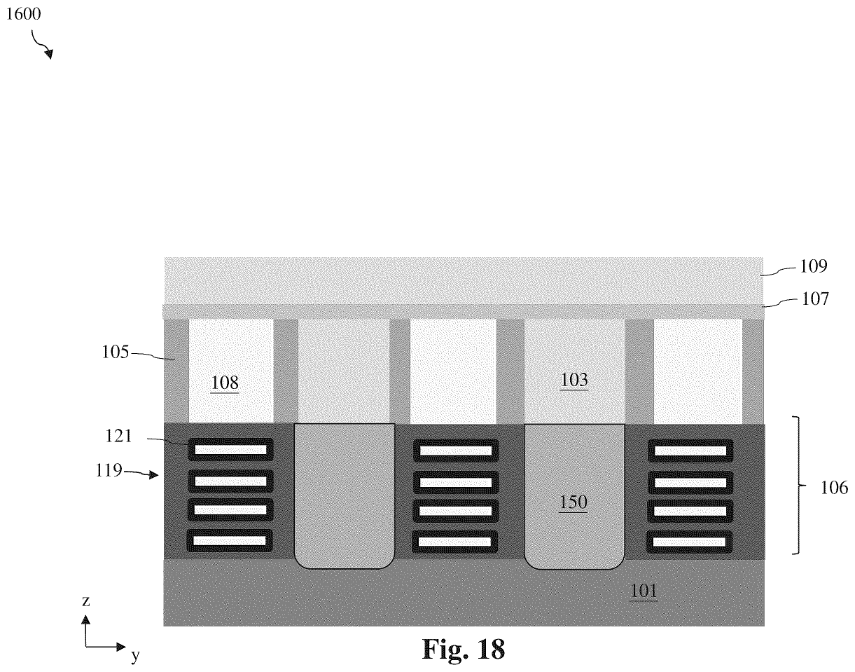

Still referring to operation 1410 but in reference to FIG. 18, the method 1400 may include depositing a dielectric layer 109 over the etch stop layer 107. The dielectric layer 109 may have substantially the same material composition as the dielectric layer 103.

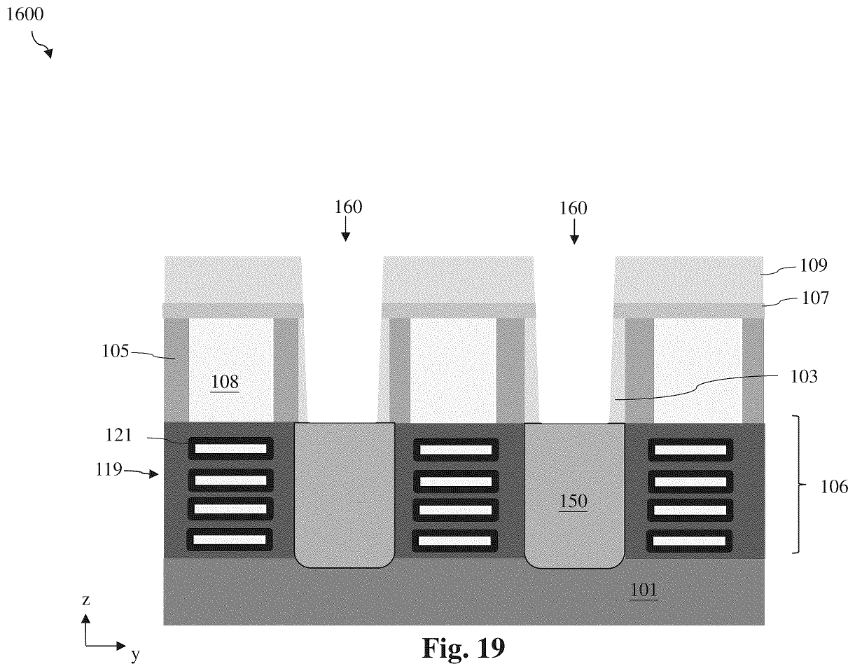

At operation 1420, in reference to FIG. 19, the method 1400 forms S/D trenches 160 to expose top surfaces of the S/D epitaxial features 150. The S/D trenches 160 may be formed through photolithography and etching processes. For example, the photolithography process may form a masking element covering areas of the device 1600 that are not to be etched and exposing areas that are to be etched. The S/D trenches 160 may be formed by etching through the dielectric layer 103, the etch stop layer 107, and the dielectric layer 109.

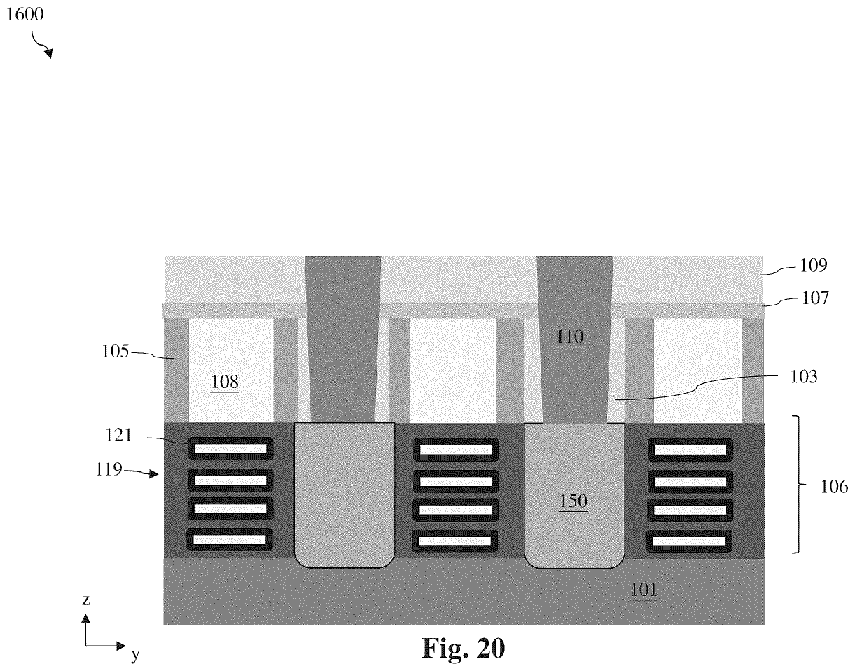

At operation 1430, in reference to FIG. 20, the method 1400 forms S/D contacts 110 in the S/D trenches 160. In this embodiment, the S/D contacts may include a metal fill material comprising tungsten (W). In other embodiments, other suitable metal fill material such as aluminum, tungsten, cobalt, and copper may be used.

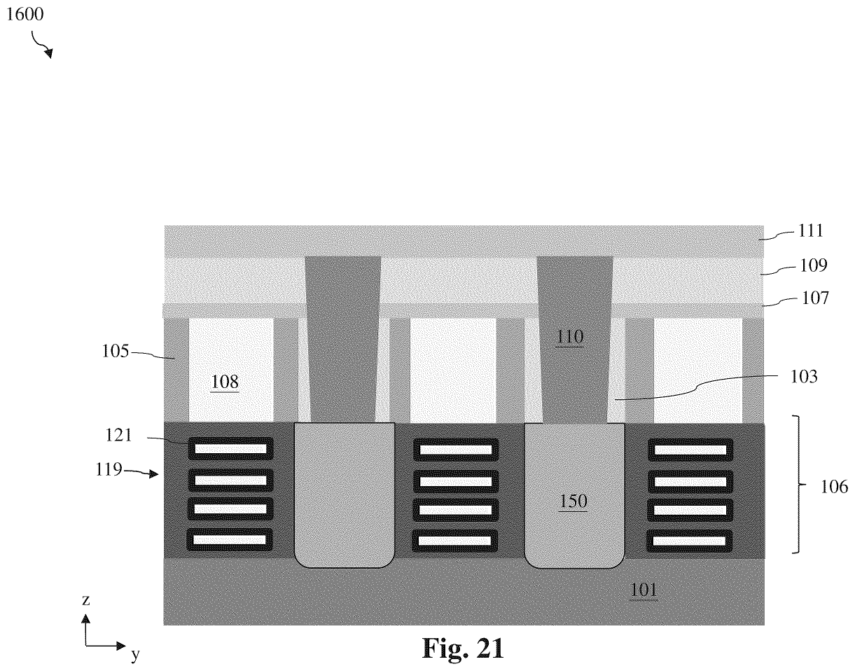

At operation 1440, in reference to FIG. 21, the method 1400 may include forming an etch stop layer 111 over top surfaces of the dielectric layer 109 and the S/D contacts 110. The etch stop layer 111 may be similar to the etch stop layer 107. However, in some embodiments, the etch stop layer 111 may be thicker in the z direction than the etch stop layer 107. The extra thickness may prepare for the formation of gate metal interconnects in a later process step.

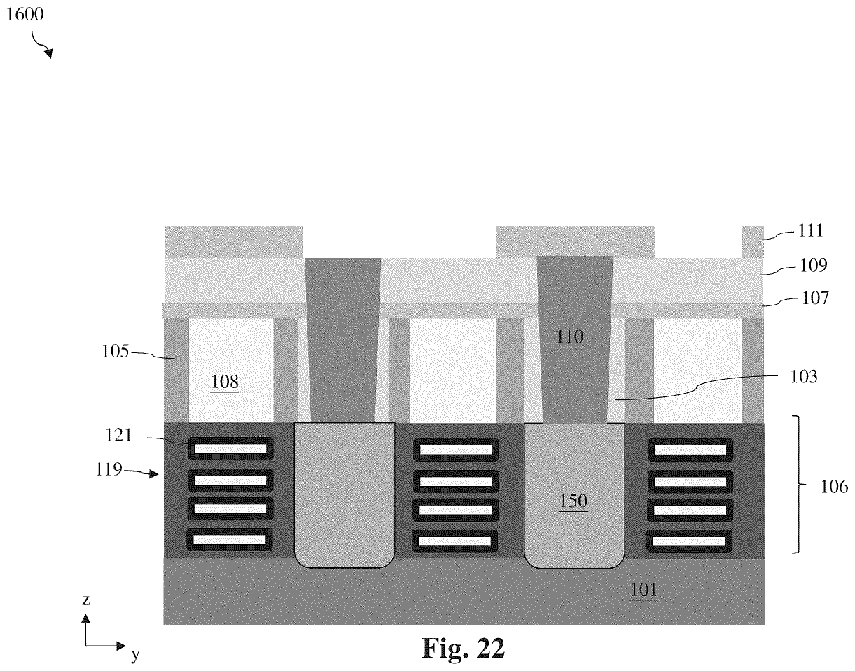

At operation 1450, in reference to FIG. 22, the method 1400 may include patterning the etch stop layer 111 to expose portions of the dielectric layer 109 that are directly above the gate structures 108. In some embodiments, the patterning also includes exposing a top surface of one of the S/D contacts 110.

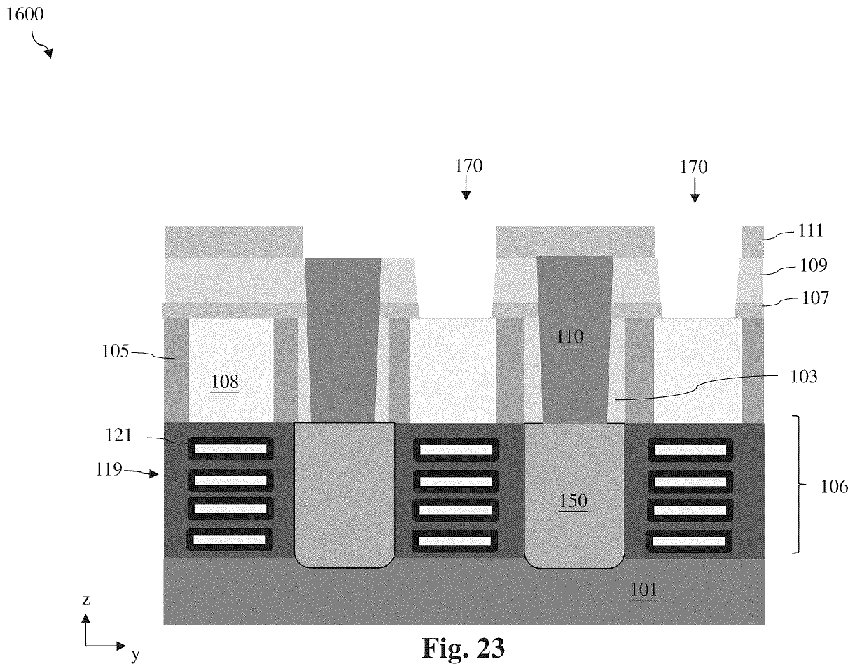

At operation 1460, in reference to FIG. 23, the method 1400 may include forming gate trenches 170 to expose top surfaces of the gate structures 108. The trenches 170 may be formed by etching through the etch stop layer 111, the dielectric layer 109, and the etch stop layer 107. This process may include a single etching step or multiple etching steps.

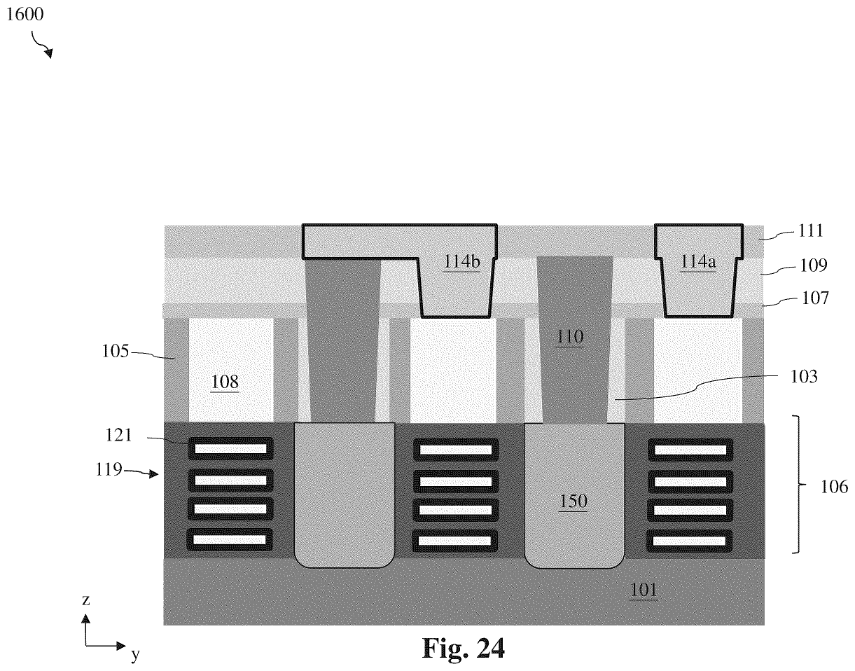

At operation 1470, in reference to FIG. 24, the method 1400 may include forming metal gate interconnects 114a and 114b in the openings formed by the patterning of the etch stop layer 111 and the trenches 170. The metal gate interconnects 114a and 114b each directly land on respective gate structures 108. In this embodiment, the metal gate interconnects 114a and 114b may include a metal fill material comprising tungsten (W). As such, the metal fill material for the S/D contacts 110 and the metal gate interconnects 114a and 114b are substantially the same. In other embodiments, the metal fill material for the S/D contacts and the metal gate interconnects are still of the same composition, but the metal fill material may include other metals such as molybdenum (Mo) or ruthenium (Ru). As explained below, having the same or similar metal compositions for different metal contacts is advantageous for simultaneous metal growth in later processing steps. Even so, the present disclosure is not limited to the S/D contacts and the metal gate interconnects having the same metal compositions.

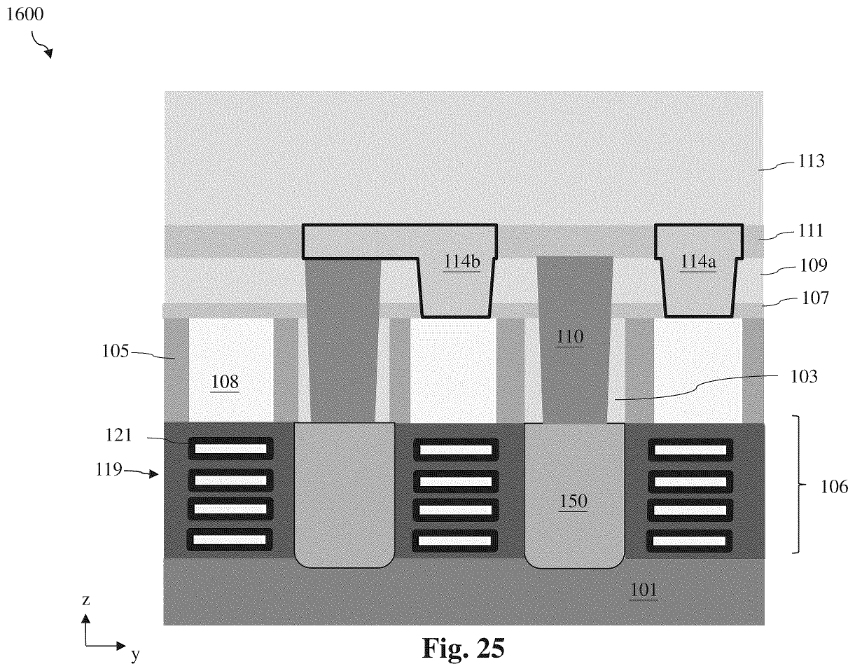

At operation 1480, in reference to FIG. 25, the method 1400 may include forming a dielectric layer 113 over the metal gate interconnects 114a and 114b. The dielectric layer 113 may also form over the etch stop layer 111. The dielectric layer 113 may have substantially the same material composition as the dielectric layer 103.

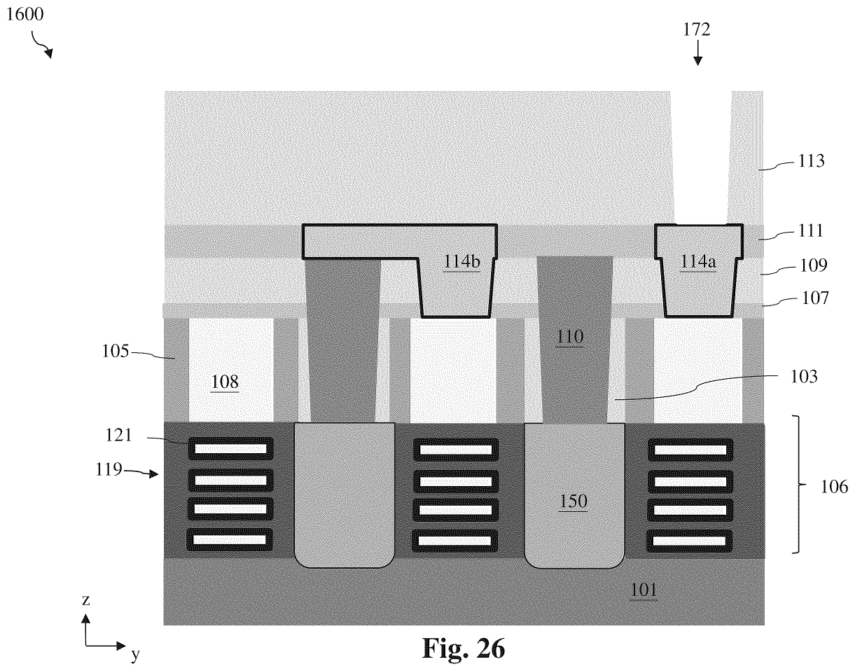

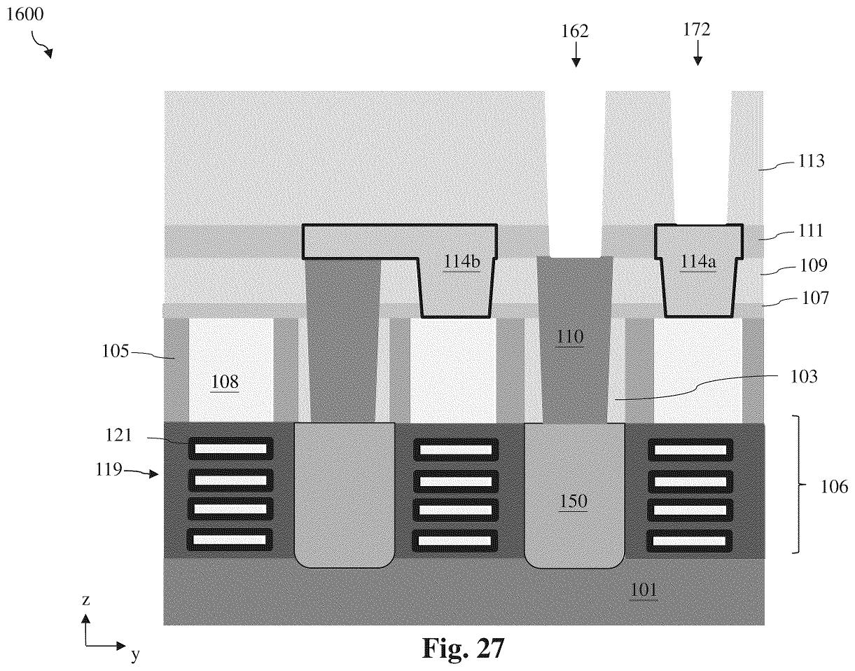

At operation 1490, in reference to FIG. 26, the method 1400 may include forming a gate trench 172 to expose a top surface of the metal gate interconnect 114a. The gate trench 172 may be formed by etching through the dielectric layer 113. At operation 1520 and in reference to FIG. 27, the method 1400 (FIG. 14) may include forming a S/D trench 162 to expose a top surface of one of the S/D contacts 110. The S/D trench 162 is etched deeper than the gate trench 172. In some embodiments, the S/D trenches is etched through the dielectric layer 113 and the etch stop layer 111. As shown here, the trenches 162 and 172 are formed separately in separate steps. However, in other embodiments, the trenches 162 and 172 may be formed in the same processing steps.

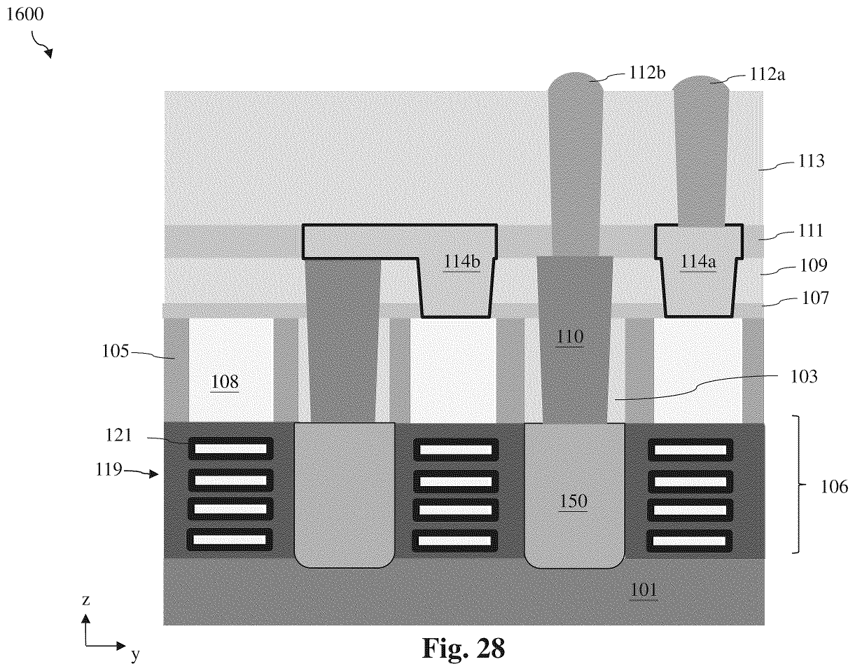

At operation 1500 and operation 1530, in reference to FIG. 28, the method 1400 may include forming a gate via 112a in the gate trench 172 (operation 1500) and a S/D via 112b in the S/D trench 162 (operation 1530). In this embodiment, the gate and the S/D vias 112a and 112b are formed simultaneously in a single processing step. The metal fill selection for the S/D contact 110 and the metal gate interconnect 114a allows for barrier free simultaneous metal growth of the gate and the S/D vias 112a and 112b. This is because the metal fill for the S/D contact and the metal gate interconnect is strategically chosen to be the same or having substantially similar metal compositions (e.g., both W or both Mo). This allows for a same metal growth rate for the vias 112a and 112b in a bottom-up metal growth scheme. In some embodiments, the metal fill for the vias 112a and 112b may include W or Mo.

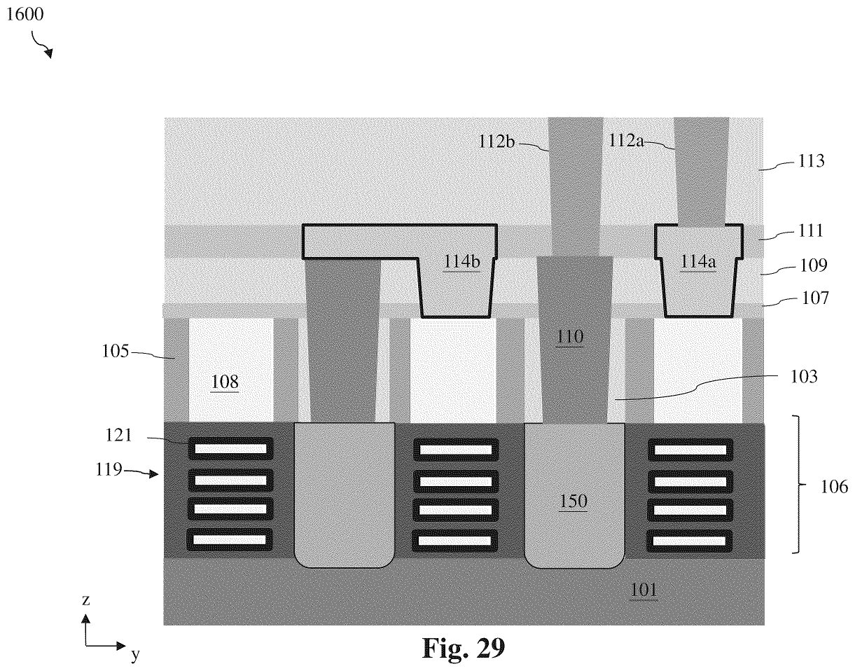

Still referring to operations 1500 and 1530, now in reference to FIG. 29, the method 1400 may include a chemical mechanical planarization (CMP) step to level off the device 1600. The CMP step planarizes the device 1600 such that top surfaces of the dielectric layer 113 and top surfaces of the vias 112a and 112b are coplanar.

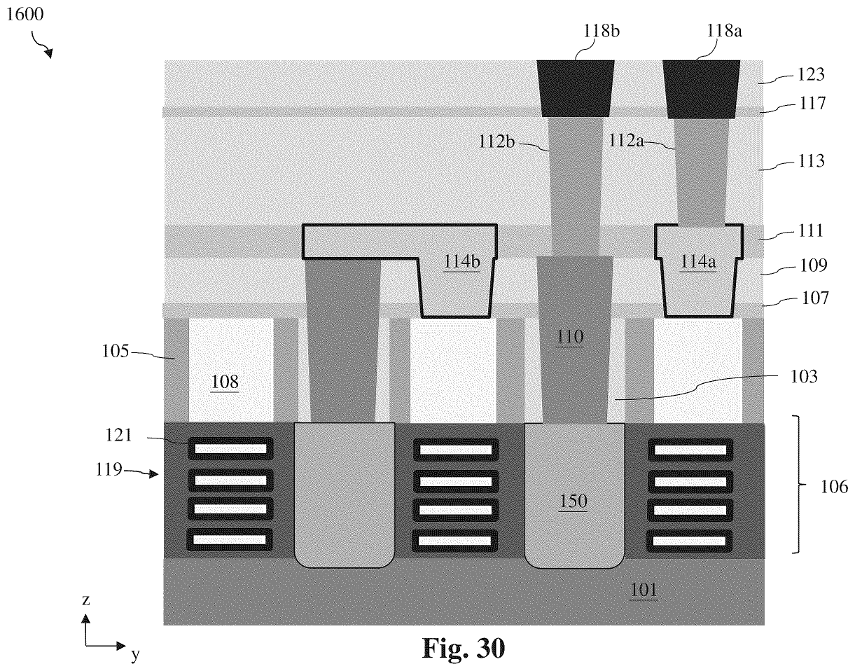

At operation 1510 and operation 1540, and in reference to FIG. 30, the method 1400 may include forming an interconnect structure having metal lines 118a and 118b to couple various devices into an integrated circuit. The interconnect structure includes metal lines distributed in multiple metal layers, such as a first metal layer, a second metal layer over the first metal layer, to an n^{th} metal layer over an (n−1)^{th} metal layer, and a top metal layer. Particularly, the first metal layer includes a plurality of metal lines, such as a first metal line 118a over the gate via 112a (operation 1510) and a second metal line 118b over the S/D via 112b (operation 1540). In the disclosed embodiment, the first and the second metal lines 118a and 118b are formed simultaneously in a single processing step. In the disclosed embodiment, the metal lines 118a and 118b include the same metal materials. In some embodiments, the metal lines 118a and 118b are embedded in another dielectric layer 123 and may penetrate through another etch stop layer 117 to land on the gate via 112a and S/D via 112b respectively.

Although not intended to be limiting, the present disclosure offers advantages related to gate via connections in semiconductor devices. One example advantage is that in a forksheet semiconductor device, a metal gate interconnect of the present disclosure allows reduction in metal gate height to improve parasitic capacitance issues between source/drain contacts and the metal gate. Another example advantage is that in a SRAM semiconductor device, the metal gate interconnect allows for reduction of SRAM cell size and enlargement of metal bit line dimensions. Further, having a metal gate interconnect enables low resistance and seamless barrier free metal growth for gate vias in semiconductor devices. Still further, the incorporation of the metal gate interconnect allows for simultaneous metal growth of gate vias and source/drain vias, thereby simplifying the process for forming the semiconductor device.

One aspect of the present disclosure pertains to a semiconductor device. The semiconductor device includes a forksheet structure over a substrate and extending lengthwise along a first direction. The forksheet structure has a dielectric wall separating a stack of n-type nanostructures from a stack of p-type nanostructures. A gate structure is over the forksheet structure, the gate structure extending lengthwise along a second direction perpendicular to the first direction. The gate structure is in direct contact with the stack of n-type and p-type nanostructures and in direct contact with the dielectric wall. A first gate interconnect is over and in direct contact with the gate structure and a first gate via is over and in direct contact with the first gate interconnect.

In an embodiment of the semiconductor device, the first gate interconnect is directly above the dielectric wall. In another embodiment, the first gate interconnect is directly contacting a top surface of the dielectric wall. In yet another embodiment, the first gate interconnect is directly contacting a top surface of the dielectric wall.

In an embodiment, the semiconductor device further includes a second gate interconnect over and in direct contact with the gate structure, where the second gate interconnect has a smaller dimension than that of the first gate interconnect. In another embodiment, the semiconductor device further includes a second gate via over and in direct contact with the second gate interconnect and an interconnect structure having first and second metal lines over and in direct contact with the first and the second gate vias, respectively.

In an embodiment, the semiconductor device further includes a source/drain (S/D) feature adjacent to the stack of n-type or p-type nanostructures, and an S/D contact over and in direct contact with the S/D feature and the dielectric wall. In an embodiment, a top surface of the first gate interconnect is above a top surface of the S/D contact. In an embodiment, the first gate interconnect and the S/D contact are of the same material composition. In another embodiment, the first gate interconnect and the S/D contact includes tungsten. In yet another embodiment, the semiconductor device further includes an S/D via over and in direct contact with the S/D contact, where the first gate via and the S/D via include tungsten.

Another aspect of the present disclosure pertains to a semiconductor device. The semiconductor device includes a forksheet structure over a substrate and extending lengthwise along a first direction, the forksheet structure having: a stack of nanostructures, a dielectric wall separating a first portion of the stack of nanostructures from a second portion of the stack of nanostructures, and a source/drain (S/D) feature adjacent to the stack of nanostructures. A gate structure is directly over the stack of nanostructures and extending lengthwise along a second direction perpendicular to the first direction. A cut metal gate structure is directly over the dielectric wall and separating a first portion of the gate structure from a second portion of the gate structure. An S/D contact is directly over and in direct contact with the S/D feature. A first gate interconnect is over and in direct contact with the first portion of the gate structure and the S/D contact. An interlayer dielectric (ILD) layer is over the first gate interconnect. A first metal line is over the ILD layer and extending along the first direction. And a second metal line is over the ILD layer and extending along the first direction, where the first metal line is a power line of a static random access memory (SRAM) cell, and the second metal line is a bit line of the SRAM cell.

In an embodiment of the semiconductor device, the first metal line is spaced away from the first gate interconnect at a first distance along the second direction, and the second metal line is spaced away from the first gate interconnect by a second distance along the second direction.

In an embodiment of the semiconductor device, the first metal line is directly above a portion of the first gate interconnect, and the second metal line is spaced away from the first gate interconnect by a distance along the second direction.

In an embodiment of the semiconductor device, the second metal line is directly above a portion of the first gate interconnect, and the first metal line is spaced away from the first gate interconnect by a distance along the second direction.

In an embodiment of the semiconductor device, the second metal line is wider than the first metal line along the second direction.

In an embodiment, the semiconductor device further includes a second gate interconnect over and in direct contact with the second portion of the gate structure. In an embodiment, the semiconductor device further includes a gate via directly over and contacting the second gate interconnect, the gate via surrounded by the ILD layer, and a third metal line over the ILD layer and over the gate via, the third metal line in direct contact with the gate via and extending along the first direction.

Another aspect of the present disclosure pertains to a method of forming a semiconductor device. The method includes receiving a workpiece having a gate structure over a channel region, a source/drain (S/D) feature adjacent to the channel region, a first interlayer dielectric (ILD) layer directly over the S/D feature, and a second ILD layer directly over the first ILD layer and directly over the gate structure. The method includes forming an S/D trench through the first and the second ILD layers to expose a top surface of the S/D feature. The method includes forming an S/D contact in the S/D trench. The method includes forming an etch stop layer over the second ILD layer and over the S/D contact. The method includes patterning the etch stop layer to expose a first portion of the second ILD layer directly above the gate structure. The method includes forming a first gate trench through the exposed first portion of the second ILD layer to expose a top surface of the gate structure. The method includes forming a gate interconnect structure in the gate trench. The method includes forming a third ILD layer directly over the gate interconnect structure. The method includes forming a second gate trench through the third ILD layer to expose a top surface of the gate interconnect structure. The method includes forming a gate via in the second gate trench. And the method includes forming a first metal line over the gate via.

In an embodiment of the method of forming the semiconductor device, the method further includes forming a second S/D trench through the third ILD layer and the etch stop layer to expose a top surface of the S/D contact. And the method includes forming a S/D via in the second S/D trench and forming a second metal line over the S/D via, where the gate via and the S/D via are formed in a same process step.

In an embodiment of the method of forming the semiconductor device, the S/D contact and the gate interconnect structure are of the same material composition.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor device, comprising:
a forksheet structure over a substrate and extending lengthwise along a first direction, the forksheet structure having a dielectric wall separating a stack of n-type nanostructures from a stack of p-type nanostructures;
a gate structure over the forsksheet structure and extending lengthwise along a second direction perpendicular to the first direction, the gate structure in direct contact with the stack of n-type and p-type nanostructures and in direct contact with the dielectric wall;
a first gate interconnect over and in direct contact with the gate structure; and
a first gate via over and in direct contact with the first gate interconnect.

2. The semiconductor device of claim 1, wherein the first gate interconnect is directly above the dielectric wall.

3. The semiconductor device of claim 2, wherein the first gate interconnect is directly contacting a top surface of the dielectric wall.

4. The semiconductor device of claim 1, wherein a width of the first gate interconnect is greater than a width of the dielectric wall along the second direction.

5. The semiconductor device of claim 2, further comprising a second gate interconnect over and in direct contact with the gate structure, wherein the second gate interconnect has a smaller dimension than that of the first gate interconnect.

6. The semiconductor device of claim 5, further comprising:
a second gate via over and in direct contact with the second gate interconnect; and
an interconnect structure having first and second metal lines over and in direct contact with the first and the second gate vias, respectively.

7. The semiconductor device of claim 1, further comprising:
a source/drain (S/D) feature adjacent to the stack of n-type or p-type nanostructures; and
an S/D contact over and in direct contact with the S/D feature and the dielectric wall,
wherein a top surface of the first gate interconnect is above a top surface of the S/D contact.

8. The semiconductor device of claim 7, wherein the first gate interconnect and the S/D contact are of the same material composition.

9. The semiconductor device of claim 8, wherein the first gate interconnect and the S/D contact includes tungsten.

10. The semiconductor device of claim 9, further comprising:
an S/D via over and in direct contact with the S/D contact,
wherein the first gate via and the S/D via include tungsten.

11. A semiconductor device, comprising:
a forksheet structure over a substrate and extending lengthwise along a first direction, the forksheet structure having:
a stack of nano structures;
a dielectric wall separating a first portion of the stack of nanostructures from a second portion of the stack of nanostructures; and
a source/drain (S/D) feature adjacent to the stack of nano structures;
a gate structure directly over the stack of nanostructures and extending lengthwise along a second direction perpendicular to the first direction;
a cut metal gate structure directly over the dielectric wall and separating a first portion of the gate structure from a second portion of the gate structure;
an S/D contact directly over and in direct contact with the S/D feature;
a first gate interconnect over and in direct contact with the first portion of the gate structure and the S/D contact;
an interlayer dielectric (ILD) layer over the first gate interconnect;
a first metal line over the ILD layer and extending along the first direction; and
a second metal line over the ILD layer and extending along the first direction,
wherein the first metal line is a power line of a static random access memory (SRAM) cell, and the second metal line is a bit line of the SRAM cell.

12. The semiconductor device of claim 11, wherein the first metal line is spaced away from the first gate interconnect at a first distance along the second direction, and the second metal line is spaced away from the first gate interconnect by a second distance along the second direction.

13. The semiconductor device of claim 11, wherein the first metal line is directly above a portion of the first gate interconnect, and the second metal line is spaced away from the first gate interconnect by a distance along the second direction.

14. The semiconductor device of claim 11, wherein the second metal line is directly above a portion of the first gate interconnect, and the first metal line is spaced away from the first gate interconnect by a distance along the second direction.

15. The semiconductor device of claim 14, wherein the second metal line is wider than the first metal line along the second direction.

16. The semiconductor device of claim 11, further comprising a second gate interconnect over and in direct contact with the second portion of the gate structure.

17. The semiconductor device of claim 16, further comprising:
a gate via directly over and contacting the second gate interconnect, the gate via surrounded by the ILD layer; and
a third metal line over the ILD layer and over the gate via, the third metal line in direct contact with the gate via and extending along the first direction.

18. A method of forming a semiconductor device, comprising:
receiving a workpiece having a gate structure over a channel region, a source/drain (S/D) feature adjacent to the channel region, a first interlayer dielectric (ILD) layer directly over the S/D feature, and a second ILD layer directly over the first ILD layer and directly over the gate structure;
forming an S/D trench through the first and the second ILD layers to expose a top surface of the S/D feature;
forming an S/D contact in the S/D trench;
forming an etch stop layer over the second ILD layer and over the S/D contact;
patterning the etch stop layer to expose a first portion of the second ILD layer directly above the gate structure;
forming a first gate trench through the exposed first portion of the second ILD layer to expose a top surface of the gate structure;
forming a gate interconnect structure in the gate trench;
forming a third ILD layer directly over the gate interconnect structure;
forming a second gate trench through the third ILD layer to expose a top surface of the gate interconnect structure;
forming a gate via in the second gate trench; and
forming a first metal line over the gate via.

19. The method of claim 18, further comprising:
forming a second S/D trench through the third ILD layer and the etch stop layer to expose a top surface of the S/D contact;
forming a S/D via in the second S/D trench; and
forming a second metal line over the S/D via,
wherein the gate via and the S/D via are formed in a same process step.

20. The method of claim 18, wherein the S/D contact and the gate interconnect structure are of the same material composition.
